(19) United States
(12) Patent Application Publication
(10) Pub. No.: US 2026/0123149 A1
(43) Pub. Date: Apr. 30, 2026

(54) DISPLAY DEVICE AND METHOD FOR MANUFACTURING THE SAME AND ELECTRONIC DEVICE

(71) Applicant: Samsung Display Co., Ltd., Yongin-si (KR)

(72) Inventors: Hyun Won KIM, Yongin-si (KR); Jong Duk ROH, Yongin-si (KR); Mi Hyang SHEEN, Yongin-si (KR); Tae Kyu KIM, Yongin-si (KR); Jae Han LEE, Yongin-si (KR)

(21) Appl. No.: 19/288,627

(22) Filed: Aug. 1, 2025

(30) Foreign Application Priority Data
Oct. 31, 2024 (KR) 10-2024-0152393

(51) Int. Cl. H10H 29/80; H10H 29/01

(52) U.S. Cl. CPC H10H 29/8321; H10H 29/012; H10H 29/032

(57) ABSTRACT

A display device, a method for manufacturing the same, and an electronic device are provided. A display device includes a substrate, a pixel electrode and a common electrode above the substrate, and spaced apart from each other, a light-emitting element including a first contact electrode contacting the pixel electrode, and a second contact electrode contacting the common electrode, a first repair material between the pixel electrode and the first contact electrode, and including an organic material including conductive particles, and a second repair material between the common electrode and the second contact electrode, having a volume that is larger than a volume of the first repair material, and including an organic material including conductive particles.

### CROSS-REFERENCE TO RELATED APPLICATION

The present application claims priority to, and the benefit of, Korean Patent Application No. 10-2024-0152393, filed on Oct. 31, 2024, in the Korean Intellectual Property Office, the entire disclosure of which is incorporated herein by reference.

### BACKGROUND

### 1. Field

The present disclosure relates to a display device, a method for manufacturing the same, and an electronic device.

### 2. Description of the Related Art

As the information society develops, the demand for display devices for displaying images is increasing in various forms. The display device may be a flat panel display device, such as a liquid crystal display, a field emission display, a light-emitting display, and the like.

The light-emitting display device may include an organic light-emitting display device including an organic light-emitting diode element as a light-emitting element, and an ultra-small light-emitting display device including a micro light-emitting diode element (hereinafter referred to as a micro light-emitting element) as a light-emitting element. Because the micro light-emitting diode element is made of an inorganic material, it may have a relatively long lifespan due to less deterioration issues compared to an organic light-emitting diode element.

Aspects of embodiments of the present disclosure provide a display device and a manufacturing method that may reduce or minimize the risk of resistance increase between a repair material/repair bonding material and a contact electrode of a light-emitting element without an additional process operation.

However, the present disclosure is not limited to those set forth herein. The above and other embodiments of the present disclosure will become more apparent to one of ordinary skill in the art to which the present disclosure pertains by referencing the detailed description of the present disclosure given below.

According to one or more embodiments of the present disclosure, a display device includes a substrate, a pixel electrode and a common electrode above the substrate, and spaced apart from each other, a light-emitting element including a first contact electrode contacting the pixel electrode, and a second contact electrode contacting the common electrode, a first repair material between the pixel electrode and the first contact electrode, and including an organic material including conductive particles, and a second repair material between the common electrode and the second contact electrode, having a volume that is larger than a volume of the first repair material, and including an organic material including conductive particles.

The volume of the second repair material may be about 1.1 times to about 3.0 times the volume of the first repair material.

The conductive particles may include a conductive metal or carbon black.

The light-emitting element may further include a semiconductor stack, a conductive layer on one surface of the semiconductor stack, and a protective film on three surfaces of the conductive layer, and on side surfaces of the semiconductor stack, wherein the first contact electrode is on the protective film, and is connected to the conductive layer exposed through a hole defined by the protective film, and wherein the second contact electrode is on the protective film in a hole penetrating a portion of the conductive layer and the semiconductor stack and having the second repair material filled therein.

The semiconductor stack may further include a first semiconductor layer above the conductive layer and doped with a first conductive dopant, an active layer on the first semiconductor layer, and a second semiconductor layer on the active layer and doped with a second conductive dopant.

The semiconductor stack may further include a third semiconductor layer on the second semiconductor layer and is undoped.

The semiconductor stack may further include a light extraction pattern having a concave pattern on an upper portion.

The display device may further include an organic layer between the pixel electrode and the common electrode.

The organic layer may be not above the pixel electrode and the common electrode.

The hole penetrating the portion of the conductive layer and the semiconductor stack may penetrate the conductive layer, the first semiconductor layer, and the active layer to expose the second semiconductor layer.

The second repair material may be filled in the hole penetrating the portion of the conductive layer and the semiconductor stack to a height that is higher than the active layer.

According to one or more embodiments of the present disclosure, a method for manufacturing a display device includes transferring light-emitting elements onto a pixel electrode and a common electrode, inspecting a lighting status of the light-emitting elements, removing a defective light-emitting element, and bonding a repair light-emitting element to a position corresponding to the removed defective light-emitting element using a first repair material including an organic material including conductive particles applied onto the pixel electrode, and a second repair material including an organic material including conductive particles applied onto the common electrode, an amount of the first repair material being different from an amount of the second repair material.

The bonding the repair light-emitting element to the position may include applying the first repair material to a first height using a dispenser or an inkjet, and applying the second repair material to a second height that is higher than the first height.

The repair light-emitting element may include a semiconductor stack, a conductive layer on one surface of the semiconductor stack, a protective film on three surfaces of the conductive layer, and on side surfaces of the semiconductor stack, a first contact electrode on the protective film, and connected to the conductive layer exposed through a hole defined by the protective film, and a second contact electrode on the protective film, and in a hole penetrating the conductive layer and a portion of the semiconductor stack, wherein the first contact electrode is aligned on the first repair material and the second contact electrode is aligned on the second repair material to bond the repair light-emitting element on the pixel electrode and the common electrode.

The second repair material may fill the hole penetrating the conductive layer and the portion of the semiconductor stack.

The transferring the light-emitting elements onto the pixel electrode and the common electrode may include locating an organic layer on the pixel electrode and the common electrode, arranging one of the light-emitting elements on the organic layer, locating a first connection electrode connecting the first contact electrode and the pixel electrode, and locating a second connection electrode connecting the second contact electrode and the common electrode.

The amount of the second repair material may be about 1.1 times to about 3.0 times the amount of the first repair material.

The conductive particles may include a conductive metal or carbon black.

The transferring the light-emitting elements onto the pixel electrode and the common electrode may include contacting one of the light-emitting elements onto the pixel electrode and the common electrode using a bonding metal.

According to one or more embodiments of the present disclosure, an electronic device includes a display device for displaying an image, the display device including a substrate, a pixel electrode and a common electrode above the substrate, and spaced apart from each other, a light-emitting element including a first contact electrode contacting the pixel electrode, and a second contact electrode contacting the common electrode, a first repair material between the pixel electrode and the first contact electrode, and including an organic material including conductive particles, and a second repair material between the common electrode and the second contact electrode, having a volume that is larger than a volume of the first repair material, and including an organic material including conductive particles.

According to the display device and the manufacturing method thereof according to the embodiments, the risk of resistance increase between a repair bonding and a contact electrode of a light-emitting element may be reduced or minimized without a separate additional process. Also, the risk of short-circuiting between a pixel electrode and a common electrode may be reduced or minimized.

However, the effects of the present disclosure are not limited to the aforementioned effects, and various other effects are included in the present specification.

### BRIEF DESCRIPTION OF THE DRAWINGS

FIG. 1 is a perspective view illustrating a display device according to one or more embodiments.

FIG. 2 is a layout diagram illustrating a display device according to one or more embodiments.

FIG. 3 is a block diagram illustrating a display device according to one or more embodiments.

FIG. 4 is an equivalent circuit diagram illustrating a sub-pixel according to one or more embodiments.

FIG. 5 is a layout diagram illustrating pixels of a display area according to one or more embodiments.

FIG. 6 is a cross-sectional view illustrating one display panel taken across the line I-I′ in FIG. 5.

FIG. 7 is a cross-sectional view illustrating an area A in FIG. 6 in detail.

FIG. 8 is a cross-sectional view illustrating another example of area B of FIG. 6 in detail.

FIG. 9 is a cross-sectional view illustrating another example of a cross-section of the display panel corresponding to the line I-I′ of FIG. 5.

FIG. 10 is a cross-sectional view illustrating another example of area A2 of FIG. 9 in detail.

FIG. 11 is a cross-sectional view illustrating the repair light-emitting element and repair material of FIG. 9.

FIG. 12 is a flowchart illustrating a method of manufacturing a display device according to one or more embodiments.

FIGS. 13 to 19 are example drawings to illustrate a method of manufacturing a display device according to one or more embodiments.

FIG. 20 is a graph illustrating the magnitude of current versus voltage of a light-emitting element bonded using a repair material according to one or more embodiments.

FIG. 21 is a graph illustrating the magnitude of current versus voltage of a light-emitting element bonded using a conventional bonding metal.

FIG. 22 is an image of a repair light-emitting element using a repair material according to one or more embodiments.

FIG. 23 is an image of a repair light-emitting element using a conventional bonding metal.

FIG. 24 is a view of a smart watch including a display device according to one or more embodiments.

FIGS. 25 and 26 are views of a virtual reality (VR) device including a display device according to one or more embodiments.

FIG. 27 is a view of a VR device including a display device according to one or more embodiments.

FIG. 28 is a view illustrating a vehicle instrument cluster and center fascia including display devices according to one or more embodiments.

FIG. 29 is a view of a transparent display device including a display device according to one or more embodiments.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing one or more embodiments corresponds to one or more embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component (e.g., an apparatus, a device, a circuit, a wire, an electrode, a terminal, a conductive film, etc.) is referred to as being “formed on,” “on,” “connected to,” or “(operatively, functionally, or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a transistor, a resistor, an inductor, a capacitor, a diode and/or the like. Accordingly, a connection is not limited to the connections illustrated in the drawings or the detailed description and may also include other types of connections. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XY, YZ, and XZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When “C to D” is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.” Furthermore, the expression “being the same” may mean “being substantially the same”. In other words, the expression “being the same” may include a range that can be tolerated by those of ordinary skill in the art. The other expressions may also be expressions from which “substantially” has been omitted.

In some embodiments well-known structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

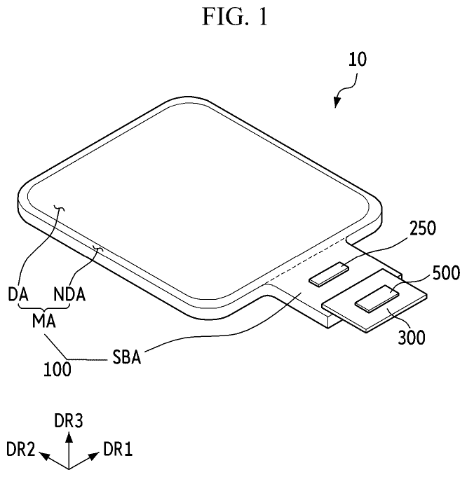

FIG. 1 is a perspective view illustrating a display device according to one or more embodiments.

Referring to FIG. 1, a display device 10 is a device for displaying video or still images, such as mobile phones, smart phones, tablet personal computers, and portable electronic devices, such as smart watches, watch phones, mobile communication terminals, electronic notebooks, e-books, portable electronic devices, such as portable multimedia players (PMP), navigation, and ultra mobile PCs (UMPC), as well as display screens for a variety of products, such as televisions, laptops, monitors, billboards, and the internet of things (IOT).

The display device 10 may be a light-emitting display device, such as an organic light-emitting display device utilizing an organic light-emitting diode, a quantum dot light-emitting display device including a quantum dot light-emitting layer, an inorganic light-emitting display device including an inorganic semiconductor, and a miniaturized light-emitting display device utilizing a micro or nano light-emitting diode (micro LED or nano LED). Hereinafter, the description focuses on the fact that the display device 10 is a micro-light-emitting display device, but the present disclosure is not limited thereto. On the other hand, a micro light-emitting diode referred to as a light-emitting element in the following for convenience of explanation.

The display device 10 includes a display panel 100, a display driver (e.g., display-driving circuit) 250, a circuit board 300, and a power supply 500.

The display panel 100 may be formed as a rectangular-shaped plane having a short side in the first direction DR1 and a long side in the second direction DR2 that crosses the first direction DR1. A corner where the short side in the first direction DR1 and the long side in the second direction DR2 meet may be rounded to have a curvature (e.g., predetermined curvature) or may be formed at a right angle. The planar shape of the display panel 100 is not limited to a rectangle, and may be formed in other polygonal, circular, or oval shapes. The display panel 100 may be flat, but is not limited thereto. For example, the display panel 100 is formed at left and right ends, and may include curved portions with a constant curvature or a changing curvature. Additionally, the display panel 100 may be flexible, such as to be able to be bent, curved, bent, folded, or rolled.

The substrate SUB of the display panel 100 may include a main area MA and a sub-area SBA.

The main area MA may include a display area DA that displays an image, and a non-display area NDA that is a peripheral area of the display area DA. The display area DA may include a plurality of pixels that display an image. For example, the pixel may include a first sub-pixel that emits first light, a second sub-pixel that emits second light, and a third sub-pixel that emits third light.

The sub-area SBA may protrude from one side of the main area MA in the second direction DR2. Although FIG. 1 illustrates the sub-area SBA being unfolded, the sub-area SBA may be bent, and in this case, may be located on the bottom surface of the display panel 100. When the sub-area SBA is bent, it may overlap the main area MA in the third direction DR3, which is the thickness direction of the display panel 100. The display driver 250 may be located in the sub-area SBA.

The display driver 250 may generate signals and voltages for driving the display panel 100. The display driver 250 may be formed as an integrated circuit (IC) and attached to the display panel 100 using a chip-on-glass (COG) method, a chip-on-plastic (COP) method, or an ultrasonic bonding method but is not limited thereto. For example, the display driver 250 may be attached to the circuit board 300 using a chip on film (COF) method.

The circuit board 300 may be attached to one end of the sub-area SBA of the display panel 100. As such, the circuit board 300 may be electrically connected to the display panel 100 and the display driver 250. The display panel 100 and the display driver 250 may receive digital video data, timing signals, and driving voltages through the circuit board 300. The circuit board 300 may be a flexible film, such as a flexible printed circuit board, a printed circuit board, or a chip on film.

The power supply 500 may generate a plurality of panel driving voltages according to an external power supply voltage. The power supply 500 may be formed as an integrated circuit (IC) and attached to the circuit board 300 using a COF method.

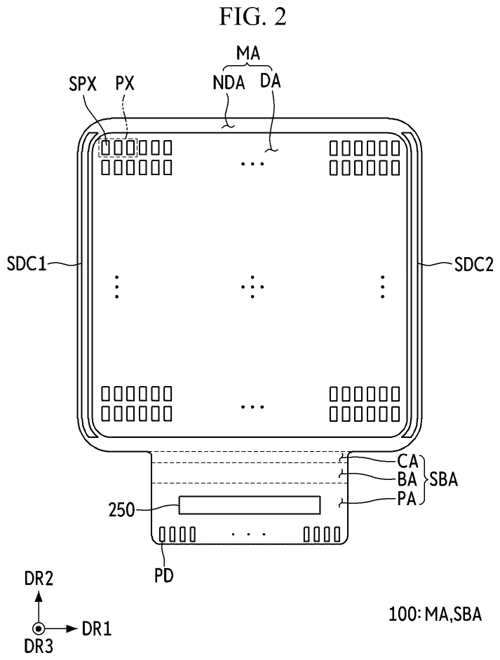

FIG. 2 is a layout diagram illustrating a display device according to one or more embodiments. FIG. 2 illustrates that the sub-area SBA is unfolded without being bent.

Referring to FIG. 2, the display panel 100 may include the main area MA and the sub-area SBA.

The main area MA may include the display area DA that displays an image, and the non-display area NDA that is a peripheral area of the display area DA. The display area DA may occupy most of the main area MA. The display area DA may be placed generally in the center of the main area MA.

The display area DA may include a plurality of pixels PX for displaying an image, and each of the plurality of pixels PX may include a plurality of sub-pixels SPX. A pixel PX may be defined as a sub-pixel group of the smallest unit capable of expressing a white grayscale.

The non-display area NDA may be placed adjacent to the display area DA. The non-display area NDA may be an area outside the display area DA. The non-display area NDA may be arranged to surround the display area DA. The non-display area NDA may be an edge area of the display panel 100.

A first scan driver SDC1 and a second scan driver SDC2 may be located in the non-display area NDA. The first scan driver SDC1 is located on one side (for example, the left side) of the display panel 100, and the second scan driver SDC2 is located on the other side (for example, the right side) of the display panel 100. However, it is not limited to. Each of the first scan driver SDC1 and the second scan driver SDC2 may be electrically connected to the display driver 250 through scan fan-out lines. Each of the first scan driver SDC1 and the second scan driver SDC2 may receive a scan control signal from the display driver 250, may generate scan signals according to the scan control signal, and may output them to the scan lines.

The sub-area SBA may protrude from one side of the main area MA in the second direction DR2. The length of the sub-area SBA in the second direction DR2 may be less than the length of the main area MA in the second direction DR2. The length of the first direction DR1 of the sub-area SBA is less than the length of the first direction DR1 of the main area MA or may be substantially equal to the length of the first direction DR1 of the main area MA. The sub-area SBA may be curved and may be located at the lower portion of the display panel 100. In this case, the sub-area SBA may overlap the main area MA in the third direction DR3.

The sub-area SBA may include a connection area CA, a pad area PA, and a bending area BA.

The connection area CA is an area protruding from one side of the main area MA in the second direction DR2. One side of the connection area CA may be in contact with the non-display area NDA of the main area MA, and the other side of the connection area CA may be in contact with the bending area BA.

The pad area PA is an area where the pads PD and the display driver 250 are located. The display driver 250 may be attached to the driving pads of the pad area PA using a conductive adhesive member, such as an anisotropic conductive film. The circuit board 300 may be attached to the pads PD of the pad area PA using a conductive adhesive member, such as an anisotropic conductive film. One side of the pad area PA may be in contact with the bending area BA.

The bending area BA is a bent area. When the bending area BA is bent, the pad area PA may be located below the connection area CA and below the main area MA. The bending area BA may be located between the connection area CA and the pad area PA. One side of the bending area BA may be in contact with the connection area CA, and the other side of the bending area BA may be in contact with the pad area PA.

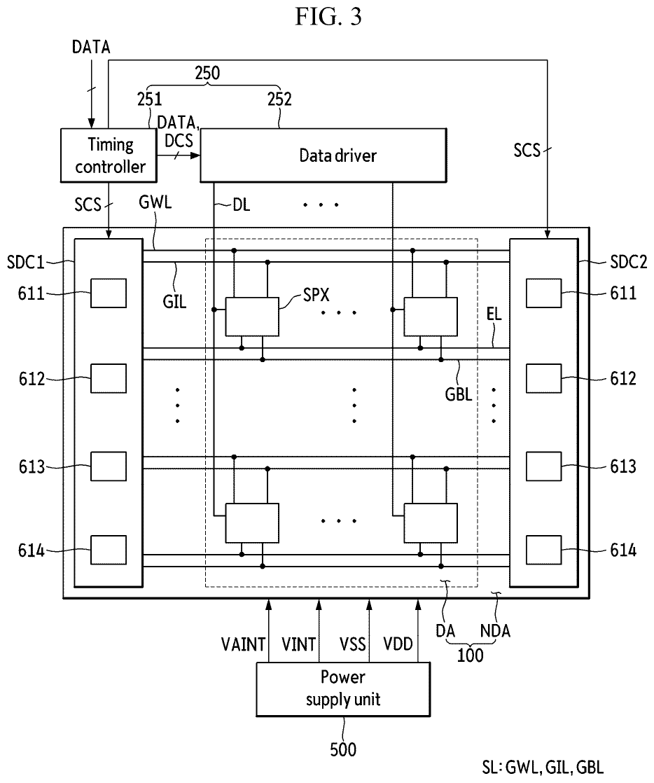

FIG. 3 is a block drawing illustrating a display device according to one or more embodiments.

Referring to FIG. 3, the display area DA includes a plurality of pixels PX including a plurality of sub-pixels SPX, a plurality of scan lines SL, a plurality of emission control lines EL, and a plurality of data lines DL.

The plurality of pixels PX may be arranged in a matrix form along the first direction DR1 and the second direction DR2. For example, the plurality of pixels PX may be arranged along rows and columns of a matrix along the first direction DR1 and the second direction DR2. The plurality of scan lines SL and the plurality of emission control lines EL may extend in the first direction DR1 and may be located along the second direction DR2. The plurality of data lines DL may extend in the second direction DR2 and be located along the first direction DR1. The plurality of scan lines SL may include a plurality of write scan lines GWL, a plurality of initialization scan lines GIL, and a plurality of bias scan lines GBL. In one or more embodiments, the plurality of scan lines SL may also include a plurality of control scan lines GCL.

Each of the plurality of sub-pixels SPX may be connected to a write scan line GWL from among the plurality of write scan lines GWL, an initialization scan line GIL from among the plurality of initialization scan lines GIL, a bias scan line GBL from among the plurality of bias scan lines GBL, an emission control line EL from among the plurality of emission control lines EL, and a data line DL from among the plurality of data lines DL. Each of the plurality of sub-pixels SPX may be supplied with a data voltage of the data line DL according to the write scan signal of the write scan line GWL and may emit light from the light-emitting elements according to the data voltage.

The non-display area NDA includes a first scan driver (e.g., a first scan-driving portion) SDC1, a second scan driver (e.g., a second scan-driving portion) SDC2, and a display driver 250.

Each of the first scan driver SDC1 and the second scan driver SDC2 may include a write scan signal output portion 611, an initialization scan signal output portion 612, a bias scan signal output portion 613, and a light-emitting signal output portion 614. Each of the write scan signal output portion 611, the initialization scan signal output portion 612, the bias scan signal output portion 613, and the light-emitting signal output portion 614 may receive a scan-timing control signal SCS from a timing controller 251. The write scan signal output portion 611 may generate write scan signals according to the scan-timing control signal SCS of the a timing controller 251, and may sequentially output them to the write scan lines GWL. The initialization scan signal output portion 612 may generate initialization scan signals according to the scan-timing control signal SCS, and may sequentially output them to the initialization scan lines GIL. The bias scan signal output portion 613 may generate bias scan signals according to the scan-timing control signal SCS, and may sequentially output them to the bias scan lines GBL. The light-emitting signal output portion 614 may generate light-emitting control signals according to the scan-timing control signal SCS, and may sequentially output them to the emission control lines EL.

The display driver 250 includes a timing controller (e.g., a timing control circuit) 251 and a data driver (e.g., a data-driving circuit) 252.

The data driver 252 may receive digital video data DATA and a data-timing control signal DCS from the timing controller 251. The data driver 252 converts digital video data DATA into analog data voltages according to the data-timing control signal DCS, and outputs them to the data lines DL. In this case, the sub-pixels SPX are selected by the write scan signals of the first scan driver SDC1 and the second scan driver SDC2, and data voltages may be supplied to the selected sub-pixels SPX.

The timing controller 251 may receive digital video data and timing signals from an external source. The timing controller 251 may generate the scan-timing control signal SCS and the data-timing control signal DCS to control the display panel 100 according to timing signals. The timing controller 251 may output the scan-timing control signal SCS to the first scan driver SDC1 and the second scan driver SDC2. The timing controller 251 may output digital video data DATA and a data-timing control signal DCS to the data driver 252.

The power supply 500 may generate a plurality of panel driving voltages according to an external power supply voltage. For example, the power supply 500 may generate and supply a first driving voltage VDD, a second driving voltage VSS, a third driving voltage VINT, and a fourth driving voltage VAINT to the display panel 100.

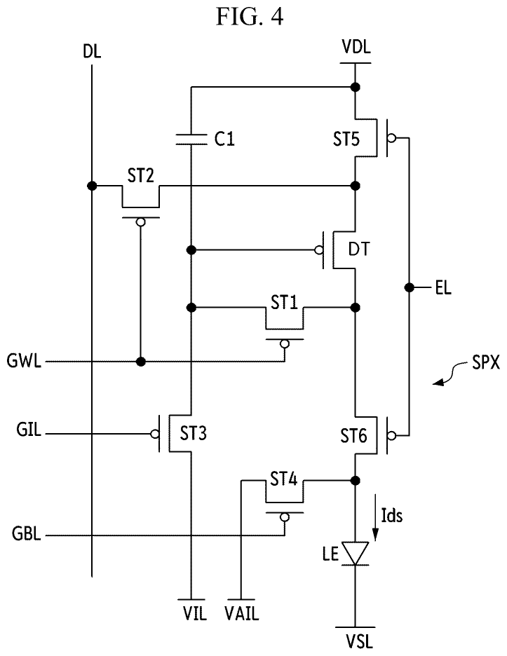

FIG. 4 is an equivalent circuit diagram of a subpixel SPX according to one or more embodiments.

Referring to FIG. 4, the subpixel SPX may be connected to scan lines GWL, GIL, and GBL, an emission control line EL, and a data line DL. For example, the subpixel SPX may be connected to a write scan line GWL, an initialization scan line GIL, a bias scan line GBL, the emission line EL, and the data line DL.

The subpixel SPX includes a driving transistor DT, switch elements, a capacitor C1, and a light-emitting element LE1. The switch elements include first through sixth transistors ST1 through ST6.

The driving transistor DT includes a gate electrode, a first electrode, and a second electrode. The driving transistor DT controls a drain-source current Ids (hereinafter, referred to as a “driving current”) flowing between the first electrode and the second electrode according to a data voltage applied to the gate electrode.

The light-emitting element LE1 may be a micro-LED. The light-emitting element LE1 emits light according to the driving current Ids. The amount of light emitted from the light-emitting element LE1 may be proportional to the driving current Ids. An anode of the light-emitting element LE1 may be connected to a first electrode of the fourth transistor ST4 and a second electrode of the sixth transistor ST6, and a cathode may be connected to a second power line VSL to which a second power supply voltage (e.g., VSS) is applied.

The capacitor C1 is formed between the gate electrode of the driving transistor DT and a first power line VDL to which a first power supply voltage (e.g., VDD) is applied. The first power supply voltage may be at a higher level than the second power supply voltage. One electrode of the capacitor C1 may be connected to the gate electrode of the driving transistor DT, and the other electrode may be connected to the first power line VDL.

As illustrated in FIG. 4, the first through sixth transistors ST1 through ST6 and the driving transistor DT may all be formed as p-type metal-oxide-semiconductor field effect transistors (MOSFETs). In this case, an active layer of each of the first through sixth transistors ST1 through ST6 and the driving transistor DT may be made of polysilicon.

A gate electrode of the first transistor ST1 and a gate electrode of the second transistor ST2 may be connected to the write scan line GWL, a gate electrode of the third transistor ST3 may be connected to the initialization scan line GIL, a gate electrode of the fourth transistor ST4 may be connected to the bias scan line GBL, and gate electrodes of the fifth and sixth transistors ST5 and ST6 may be connected to the emission line EL. Because the first through sixth transistors ST1 through ST6 are formed as p-type MOSFETs, they may be turned on when a scan signal of a gate-low voltage and an emission control signal of a gate-low voltage are transmitted to the initialization scan line GIL, the write scan line GWL, the bias scan line GBL, and the emission line EL. One electrode of the third transistor ST3 and one electrode of the fourth transistor ST4 may be connected to an initialization voltage line VIL or VAIL (e.g., respectively).

Alternatively, the driving transistor DT, the second transistor ST2, the fourth transistor ST4, the fifth transistor ST5, and the sixth transistor ST6 may be formed as p-type MOSFETs, and the first transistor ST1 and the third transistor ST3 may be formed as n-type MOSFETs. The active layer of each of the driving transistor DT, the second transistor ST2, the fourth transistor ST4, the fifth transistor ST5, and the sixth transistor ST6 formed as p-type MOSFETs may be made of polysilicon, and the active layer of each of the first transistor ST1 and the third transistor ST3 formed as n-type MOSFETs may be made of an oxide semiconductor.

In this case, because the first transistor ST1 and the third transistor ST3 are formed as n-type MOSFETs, the first transistor ST1 may be turned on in response to a scan signal of a gate-high voltage, and the third transistor ST3 may be turned on in response to an initialization scan signal of a gate-high voltage. On the other hand, because the second transistor ST2, the fourth transistor ST4, the fifth transistor ST5, and the sixth transistor ST6 are formed as p-type MOSFETs, they may be turned on in response to a scan signal of a gate-low voltage and an emission control signal.

Alternatively, the fourth transistor ST4 may be formed as an n-type MOSFET. In this case, the active layer of the fourth transistor ST4 may be made of an oxide semiconductor. When the fourth transistor ST4 is formed as an n-type MOSFET, it may be turned on in response to a scan signal of a gate-high voltage.

Alternatively, the first through sixth transistors ST1 through ST6 and the driving transistor DT may all be formed as n-type MOSFETs. In this case, the active layer of each of the first through sixth transistors ST1 through ST6 and the driving transistor DT may be made of an oxide semiconductor.

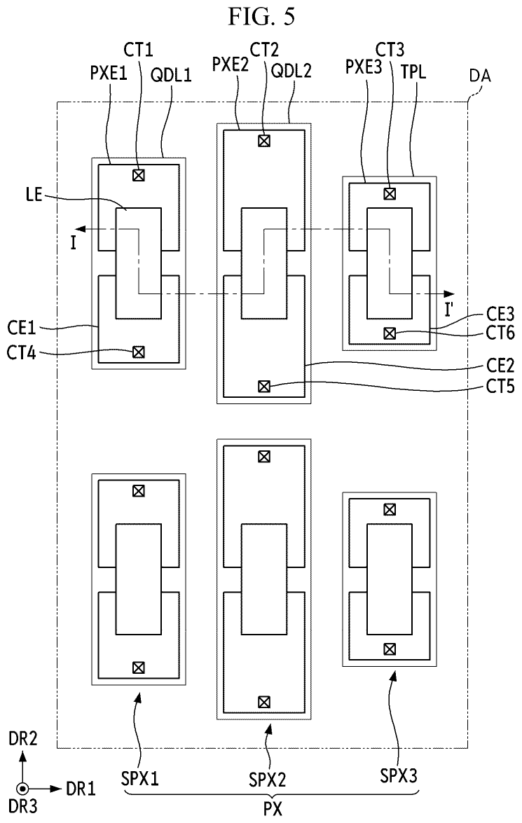

FIG. 5 is a layout diagram illustrating pixels of a display area according to one or more embodiments.

Referring to FIG. 5, each of the plurality of pixels PX of the display area DA may include three sub-pixels SPX1, SPX2, and SPX3, but the present disclosure is not limited thereto and may include four sub-pixels. When each of the plurality of pixels PX includes three sub-pixels SPX1, SPX2, and SPX3, the first sub-pixel SPX1, the second sub-pixel SPX2, and the third sub-pixel SPX3 may include.

The plurality of pixels PX may be located in a matrix form. In each of the plurality of pixels PX, the first sub-pixel SPX1, the second sub-pixel SPX2, and the third sub-pixel SPX3 may be located in a first direction DR1.

When each of the plurality of pixels PX includes three sub-pixels SPX1, SPX2, and SPX3, the first sub-pixel SPX1 may emit light of a first color, and the second sub-pixel SPX2 may emit light of a second color, and the third sub-pixel SPX3 may emit light of a third color. Here, the light of the first color may be light in the green wavelength band, the light of the second color may be light in the red wavelength band, and the light of the third color may be light in the blue wavelength band. For example, the blue wavelength band may refer to light having a main peak wavelength in the wavelength band from approximately 370 [symbol] to approximately 460 [symbol] , the green wavelength band may refer to light having a main peak wavelength in the wavelength band from approximately 480 [symbol] to approximately 560 [symbol] , and the red wavelength band may refer to light having a main peak wavelength in the wavelength band from approximately 600 [symbol] to approximately 750 [symbol] .

Alternatively, when each of the plurality of pixels PX includes four sub-pixels, the first sub-pixel may emit light of a first color, the second and fourth sub-pixels may emit light of a second color, and the third sub-pixel may emit light of a third color. Alternatively, the first sub-pixel may emit light of a first color, the second sub-pixel may emit light of a second color, the third sub-pixel may emit light of a third color, and the fourth sub-pixel may emit light of a fourth color. In this case, the fourth color light may be white light.

The first sub-pixel SPX1 includes a first pixel electrode PXE1, one or more light-emitting elements LE, and a first light conversion layer QDL1. The second sub-pixel SPX2 includes a second pixel electrode PXE2 one or more light-emitting elements LE, and a second light conversion layer QDL2. The third sub-pixel SPX3 includes a third pixel electrode PXE3, one or more light-emitting elements LE, and a third light conversion layer QDL3.

Each of the first pixel electrode PXE1, the second pixel electrode PXE2, and the third pixel electrode PXE3 may have a rectangular planar shape having a short side in the first direction DR1 and a long side in the second direction DR2. The area of the first sub-pixel SPX1, the area of the second sub-pixel SPX2, and the area of the third sub-pixel SPX3 may be set according to the light conversion efficiency of the first light conversion layer QDL1 and the light conversion efficiency of the second light conversion layer QDL2. For example, the area of the sub-pixel may become larger as the light conversion efficiency decreases.

For example, as shown in FIG. 5, when the light conversion efficiency of the second light conversion layer QDL2 is lower than the light conversion efficiency of the first light conversion layer QDL1, the area of the second pixel electrode PXE2 may be larger than the area of the first pixel electrode PXE1. Furthermore, because the light transmission layer TPL directly transmits the light of the light-emitting element LE, while the first light conversion layer QDL1 need to convert the light, the area of the first pixel electrode PXE1 may be larger than the area of the third pixel electrode PXE3.

When the light conversion efficiency of the second light conversion layer QDL2 is lower than the light conversion efficiency of the first light conversion layer QDL1, the number of light-emitting elements located on the second pixel electrode PXE2 may be greater than the number of light-emitting elements located on the first pixel electrode PXE1. For example, one light-emitting element may be located on a first pixel electrode PXE1, and two light-emitting elements (e.g., a first type light-emitting element LE1T and a second type light-emitting element LE2T) may be located on a second pixel electrode PXE2. The first type light-emitting element LE1T and the second type light-emitting element LE2T may be connected in series.

Each of the pixel electrodes PXE1, PXE2, and PXE3 may be electrically connected to at least one transistor through the pixel connection hole CT1, CT2, and CT3. For example, each of the pixel electrodes PXE1, PXE2, and PXE3 may be electrically connected to the second electrode of the fourth transistor (ST4 in FIG. 4) and the second electrode of the sixth transistor (ST6 in FIG. 4) of the corresponding sub-pixel.

In each of the first sub-pixel SPX1, the second sub-pixel SPX2, and the third sub-pixel SPX3, pixel electrodes PXE1, PXE2, and PXE3 and common electrodes CE1, CE2, and CE3 may be located in the second direction DR2. Each of the pixel electrodes PXE1, PXE2, and PXE3 and the common electrodes CE1, CE2, and CE3 may have a rectangular plane shape, but the present disclosure is not limited thereto. The area of the first pixel electrode PXE1 may be the same as the area of the first common electrode CE1, the area of the second pixel electrode PXE2 may be the same as the area of the second common electrode CE2, and the area of the third pixel electrode PXE3 may be the same as the area of the third common electrode CE3, but the present disclosure is not limited thereto.

For example, as shown in FIG. 5, when the light conversion efficiency of the second light conversion layer QDL2 is lower than the light conversion efficiency of the first light conversion layer QDL1, the area of the second pixel electrode PXE2 may be larger than the area of the first pixel electrode PXE1, and the area of the second common electrode CE2 may be larger than the area of the first common electrode CE1. Also, because the light transmission layer TPL directly transmits the light of the light-emitting element LE, whereas the first light conversion layer QDL1 needs to convert the light, the area of the first pixel electrode PXE1 may be larger than the area of the third pixel electrode PXE3, and the area of the first common electrode CE1 may be larger than the area of the third common electrode CE3.

Each of the pixel electrodes PXE1, PXE2, and PXE3 may be electrically connected to at least one transistor through the pixel connection hole CT1, CT2, and CT3, respectively. For example, each of the pixel electrodes PXE1, PXE2, and PXE3 may be electrically connected to the second electrode of the fourth transistor (ST4 in FIG. 4) and to the second electrode of the sixth transistor (ST6 in FIG. 4) of the corresponding sub-pixel.

The first common electrode CE1 may be connected to a second power supply line VSL to which a second driving voltage VSS is applied through a first common connection hole CT4. The second common electrode CE2 may be connected to a second power supply line VSL through a second common connection hole CT5. The third common electrode CE3 may be connected to the second power supply line VSL through a third common connection hole CT6. Therefore, the second driving voltage VSS may be applied to each of the common electrodes CE1, CE2, and CE3. The pixel electrodes PXE1, PXE2, and PXE3 may be referred to as an anode electrode or a first electrode, and the common electrodes CE1, CE2, and CE3 may be referred to as a cathode electrode or a second electrode.

A plurality of light-emitting elements LE may be located on the pixel electrodes PXE1, PXE2, and PXE3 and the common electrode CE1, CE2, and CE3. Each of the plurality of light-emitting elements LE may have a rectangular planar shape, but the present disclosure is not limited thereto. For example, each of the plurality of light-emitting elements LE may have a circular planar shape.

The first light conversion layer QDL1 may completely overlap with the plurality of light-emitting elements LE of the first sub-pixel SPX1. The first light conversion layer QDL1 may convert or shift the peak wavelength of incident light into light of another corresponding peak wavelength and emit the light. For example, the first light conversion layer QDL1 may convert or shift third light emitted from the plurality of light-emitting elements LE of the first sub-pixel SPX1 into first light.

The second light conversion layer QDL2 may completely overlap with the plurality of light-emitting elements LE of the second sub-pixel SPX2. The area of the second light conversion layer QDL2 may be larger than the area of the second pixel electrode PXE2. The second light conversion layer QDL2 may convert or shift the peak wavelength of incident light into light of another corresponding peak wavelength and emit the light. For example, the second light conversion layer QDL2 may convert or shift the third light emitted from the plurality of light-emitting elements LE of the second sub-pixel SPX2 into the second light.

The light transmission layer TPL may completely overlap the plurality of light-emitting elements LE of the third sub-pixel SPX3. The light transmission layer TPL may directly transmit the incident light. For example, the light transmission layer TPL may directly transmit the third light emitted from the plurality of light-emitting elements LE of the third sub-pixel SPX3.

When the light-emitting element LE of the first sub-pixel SPX1 emits light of a first color, the light-emitting element LE of the second sub-pixel SPX2 emits light of a second color, and the light-emitting element LE of the third sub-pixel SPX3 emits light of a third color, the light conversion layers QDL1 and QDL2 and the light transmission layer TPL may be omitted.

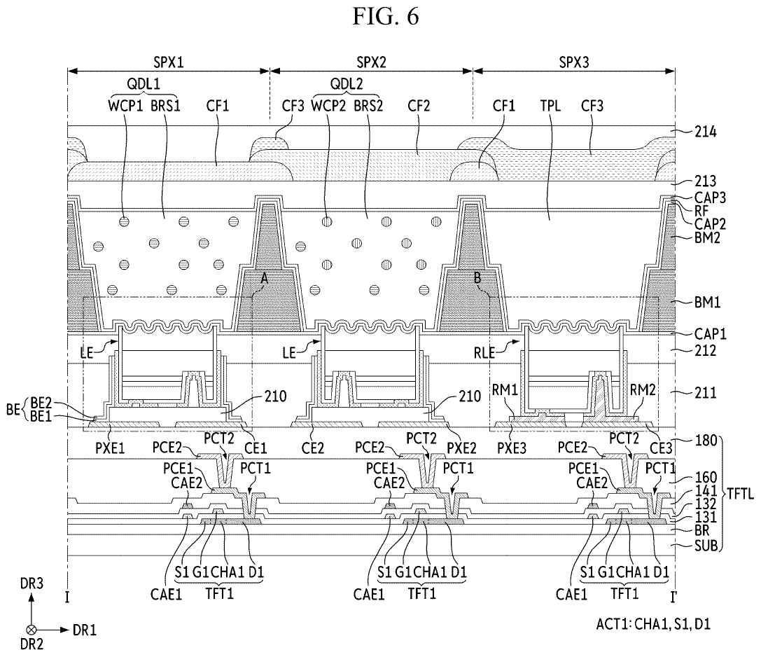

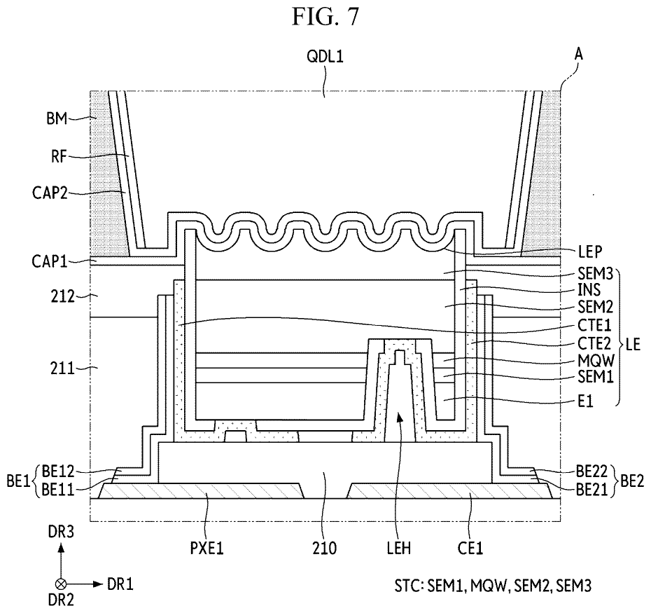

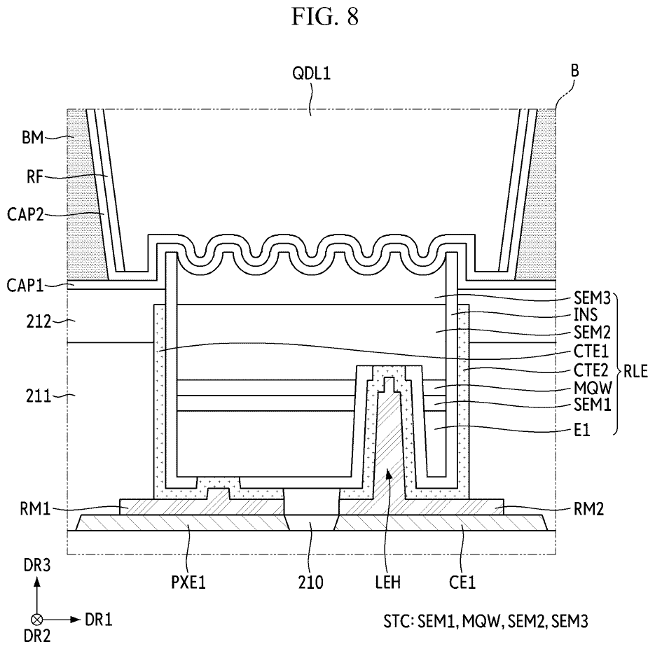

FIG. 6 is a cross-sectional view illustrating one display panel taken across the line I-I′ in FIG. 5. FIG. 7 is a cross-sectional view illustrating area A in FIG. 6 in detail. FIG. 8 is a cross-sectional view illustrating another example of area B of FIG. 6 in detail. FIG. 8 includes the repair light-emitting element and a repair material (e.g., a repair bonding material) of FIG. 6.

Referring to FIGS. 6 to 7, a substrate SUB may be made of an insulating material, such as glass, polymer resin, or the like. If the substrate SUB is made of polymer resin, it may be a flexible substrate that may be stretched. The polymer resin may be acrylic resin, epoxy resin, phenolic resin, polyamide resin, polyimide resin, or the like.

A barrier film BR may be located on the substrate SUB. The barrier film BR is a film that protects the transistors of the thin film transistor layer TFTL from moisture penetrating through the substrate SUB, which is vulnerable to moisture permeation. The barrier film BR may be formed of a plurality of inorganic films that are alternately stacked.

A thin film transistor TFT1 may be located on the barrier film BR. The thin film transistor TFT1 may be either the fourth transistor ST4 or the sixth transistor ST6 shown in FIG. 4. The thin film transistor TFT1 may include a first active layer ACT1 and a first gate electrode G1.

The first active layer ACT1 of the thin film transistor TFT1 may be located on the barrier film BR. The first active layer ACT1 of the thin film transistor TFT1 may include polycrystalline silicon, monocrystalline silicon, low-temperature polycrystalline silicon, or amorphous silicon. Alternatively, the first active layer ACT1 of the thin film transistor TFT1 may include an oxide semiconductor including IGZO (indium (In), gallium (Ga), zinc (Zn), and oxygen (O)), IGZTO (indium (In), gallium (Ga), zinc (Zn), tin (Sn), and oxygen (O)), or IGTO (indium (In), gallium (Ga), tin (Sn), and oxygen (O)).

The first active layer ACT1 may include a first channel area CHA1, a first source area S1, and a first drain area D1. The first channel area CHA1 may be an area overlapping the first gate electrode G1 in the third direction DR3, which is the thickness direction of the substrate SUB. The first source area S1 may be located on one side of the first channel area CHA1, and the first drain area D1 may be located on the other side of the first channel area CHA1. The first source area S1 and the first drain area D1 may be areas that do not overlap with the first gate electrode G1 in the third direction DR3. The first source area S1 and the first drain area D1 may be conductive areas in which semiconductor materials are doped with ions.

A first gate-insulating film 131 may be located on the first channel area CHA1, the first source area S1, and the first drain area D1 of the thin film transistor TFT1.

A first gate metal layer may be located on the first gate-insulating film 131. The first gate metal layer may include a first gate electrode G1 of a thin film transistor TFT1 and a first capacitor electrode CAE1. The first gate electrode G1 may overlap the first active layer ACT1 in the third direction DR3. Although the first gate electrode G1 and the first capacitor electrode CAE1 are illustrated as being located apart from each other in FIG. 6, the first gate electrode G1 and the first capacitor electrode CAE1 may be connected to each other.

A second gate-insulating film 132 may be located on the first gate electrode G1 and the first capacitor electrode CAE1 of the thin film transistor TFT1.

A second gate metal layer may be located on the second gate-insulating film 132. The second gate metal layer may include a second capacitor electrode CAE2. The second capacitor electrode CAE2 may overlap the first capacitor electrode CAE1 of the thin film transistor TFT1 in the third direction DR3. Because the second gate-insulating film 132 has a dielectric constant (e.g., predetermined dielectric constant), the capacitor (C1 in FIG. 4) may be formed by the first capacitor electrode CAE1, the second capacitor electrode CAE2, and the second gate-insulating film 132 located between them.

An interlayer insulating film 141 may be located on the second capacitor electrode CAE2.

A first data metal layer may be located on the interlayer insulating film 141. The first data metal layer may include a first source connection electrode PCE1. The first source connection electrode PCE1 may be connected to the first drain area D1 of the first active layer ACT1 through a first/source contact hole PCT1 penetrating the first gate-insulating film 131, the second gate-insulating film 132, and the interlayer insulating film 141.

A first planarization organic film 160 may be located on the first source connection electrode PCE1 to planarize a step caused by the thin film transistor TFT1.

A second data metal layer may be located on the first planarization organic film 160. The second data metal layer may include a second source connection electrode PCE2. The second source connection electrode PCE2 may be connected to the first source connection electrode PCE1 through a second/pixel contact hole PCT2 penetrating the first planarization organic film 160.

A second planarization organic film 180 may be located on the second source connection electrode PCE2.

The barrier film BR, the first gate-insulating film 131, the second gate-insulating film 132, the third gate-insulating film 133, and the interlayer insulating film 141 may include an inorganic film, for example, silicon nitride (SiNₓ), silicon oxide (SiON), silicon oxide (SiOₓ), titanium oxide (TiOₓ), or aluminum oxide (AlOₓ).

The first gate metal layer, the second gate metal layer, the first data metal layer, and the second data metal layer may be formed as a single layer or multiple layers of any one of molybdenum (Mo), aluminum (Al), chromium (Cr), gold (Au), titanium (Ti), nickel (Ni), neodymium (Nd), or copper (Cu), or an alloy thereof.

The first planarization organic film 160 and the second planarization organic film 180 may include an organic film, such as an acrylic resin, an epoxy resin, a phenolic resin, a polyamide resin, a polyimide resin, or the like.

A light-emitting element layer may be located on the second planarization organic film 180. The light-emitting element layer may include pixel electrodes PXE1, PXE2, PXE3, light-emitting elements LE, a common electrode CE, and an organic layer 210.

A pixel electrode layer including pixel electrodes PXE1, PXE2, and PXE3 and common electrodes CE1, CE2, and CE3 may be located on a second planarization organic film 180.

Each of the first pixel electrode PXE1, the second pixel electrode PXE2, and the third pixel electrode PXE3 may be connected to a second source connection electrode PCE2 through a connection hole (CT1/CT2/CT3 in FIG. 5) penetrating the second planarization organic film 180. Each of the pixel electrodes PXE1, PXE2, and PXE3 may be connected to a first source area S1 or a first drain area D1 of a thin film transistor TFT1 through the first source connection electrode PCE1 and the second source connection electrode PCE2. Therefore, a voltage controlled by the thin film transistor TFT1 may be applied to each of the pixel electrodes PXE1, PXE2, and PXE3.

The common electrodes CE1, CE2, and CE3 may be connected to a second power supply line (VSL in FIG. 4) to which a second driving voltage (VSS in FIG. 3) is applied through a common connection hole (CT4/CT5/CT6 in FIG. 5). The second common electrode CE2 may be connected to the second power supply line VSL through the second common connection hole CT5. The third common electrode CE3 may be connected to the second power supply line VSL through the third common connection hole CT6. Therefore, the second driving voltage VSS may be applied to each of the common electrodes CE1, CE2, and CE3.

The pixel electrode layer may be formed as a single layer or multiple layers of any one of molybdenum (Mo), aluminum (Al), chromium (Cr), gold (Au), titanium (Ti), nickel (Ni), neodymium (Nd), or copper (Cu), or alloys thereof. For example, the pixel electrode layer may be made of copper (Cu) having low surface resistance to lower the resistance of each of the pixel electrodes PXE1, PXE2, and PXE3.

The organic layer 210 may be located on each of the pixel electrode layers. For example, the organic layer 210 may cover at least a portion of the pixel electrodes PXE1 and PXE2 and at least a portion of the common electrodes CE1 and CE2.

The organic layer 210 serves to temporarily fix or adhere an upper member (e.g., a light-emitting element LE). For example, the organic layer 210 may be a film for temporarily adhering the upper member (e.g., a light-emitting element LE) on each of the pixel electrodes PXE1, PXE2, and PXE3 and the common electrodes CE1, CE2, and CE3. To facilitate the adhesion, the thickness of the organic layer 210 may be greater than the thickness of each of the pixel electrodes PXE1 and PXE2 and the common electrodes CE1 and CE2, and greater than the thickness of the contact electrode CTE. The thickness of the organic layer 210 may be about 2 [symbol] , but is not limited thereto.

The organic layer 210 may be a photosensitive organic film, such as a photoresist. Alternatively, the organic layer 210 may include an acrylic resin, an epoxy resin, a phenolic resin, a polyamide resin, a polyimide resin, or the like.

A plurality of light-emitting elements LE may be located on the organic layer 210. In FIGS. 6 and 7, the light-emitting element LE is shown as a flip-type micro LED. The flip-type micro LED refers to an LED in which contact electrodes CTE1 and CTE2 are formed on one surface (e.g., the bottom surface) of the light-emitting element LE.

The light-emitting element LE may include a substantially vertical side surface as shown in FIG. 7. For example, the light-emitting elements LE may be patterned through vertical etching and may have a rectangular or square cross-sectional shape in which the width of the top surface and the width of the bottom surface are substantially the same.

Each of the plurality of light-emitting elements LE may include an inorganic material, such as gallium nitride (GaN).

Each of the plurality of light-emitting elements LE may be formed by growing on a semiconductor substrate, such as a silicon substrate or a sapphire substrate. The plurality of light-emitting elements LE may be transferred onto the pixel electrode layer of the display panel 100 directly from the semiconductor substrate or through a relay substrate. Alternatively, the plurality of light-emitting elements LE may be transferred onto the pixel electrodes PXE1, PXE2, and PXE3 of the display panel 100 through an electrostatic method using an electrostatic head or a stamp method using an elastic polymer material, such as polydimethylsiloxane (PDMS) or silicone, as a relay substrate.

The light-emitting element LE may include a conductive layer E1, a semiconductor stack STC, a first contact electrode CTE1, a second contact electrode CTE2, and a protective film INS. The semiconductor stack STC may include a first semiconductor layer SEM1, an active layer MQW, a second semiconductor layer SEM2, and a third semiconductor layer SEM3 that are sequentially arranged in the third direction DR3.

The conductive layer E1 may be located on a bottom surface of the first semiconductor layer SEM1. In FIG. 7, the conductive layer E1 is shown as covering the entire bottom surface of the first semiconductor layer SEM1, but the embodiments of the present disclosure are not limited thereto. For example, the conductive layer E1 may be located on a portion of the bottom surface of the first semiconductor layer SEM1. The conductive layer E1 may include one of molybdenum (Mo), aluminum (Al), chromium (Cr), gold (Au), titanium (Ti), nickel (Ni), neodymium (Nd), or copper (Cu).

The first semiconductor layer SEM1 may be located on the conductive layer E1. The first semiconductor layer SEM1 may include a semiconductor material layer doped with a first conductive dopant, such as magnesium (Mg), zinc (Zn), calcium (Ca), strontium (Sr), barium (Ba), or the like, such as gallium nitride (GaN).

The active layer MQW may be located on the first semiconductor layer SEM1. The active layer MQW may emit light by combining electron-hole pairs according to an electrical signal applied through the first semiconductor layer SEM1 and the second semiconductor layer SEM2.

The active layer MQW may include a material having a single or multi-quantum well structure. When the active layer MQW includes a material having a multi-quantum well structure, it may have a structure in which a plurality of well layers and barrier layers are alternately stacked. At this time, the well layer may include indium gallium nitride (InGaN), and the barrier layer may include gallium nitride (GaN) or aluminum gallium nitride (AlGaN), but embodiments of the present disclosure are not limited thereto.

Alternatively, the active layer MQW may have a structure in which semiconductor materials having a high band gap energy and semiconductor materials having a low band gap energy are alternately stacked with each other, may include other Group III to Group V semiconductor materials according to the wavelength range of emitted light.

For example, when the active layer MQW includes InGaN, the color of the emitted light may vary depending on the content of indium (In). For example, as the content of indium (In) increases, the wavelength band of light emitted by the active layer may shift to the red wavelength band, and as the content of indium (In) decreases, the wavelength band of light emitted by the active layer may shift to the blue wavelength band. For example, the content of indium (In) in the active layer MQW of the light-emitting element LE that emits the third light (e.g., light in the blue wavelength band) may be approximately 10 wt % to approximately 20 wt %.

The second semiconductor layer SEM2 may be located on the first semiconductor layer SEM1. The second semiconductor layer SEM2 may be a semiconductor material layer doped with a second conductivity type dopant, such as silicon (Si), germanium (Ge), tin (Sn), etc., for example, gallium nitride (GaN).

The third semiconductor layer SEM3 may be referred to as an undoped semiconductor layer, which is a semiconductor material layer having an n-type dopant that is lower than a threshold value (e.g., predetermined threshold value). For example, the third semiconductor layer SEM3 may be indium aluminum gallium nitride (InAlGaN), gallium nitride (GaN), aluminum gallium nitride (AlGaN), indium gallium nitride (InGaN), aluminum nitride (AlN), or indium nitride (InN), where the n-type dopant is below a threshold (e.g., predetermined threshold).

A light extraction patterns LEP may be on the top surface of the semiconductor stack STC. For example, the light extraction patterns LEP may be on the top surface of the third semiconductor layer SEM3.

The light extraction patterns LEP may be patterns for increasing the efficiency of light emitted from the top surface of the light-emitting element LE. The light extraction patterns LEP may be concave patterns formed in a hemisphere or a semi-ellipse. The light extraction patterns LEP may be concave patterns having a cross-sectional shape of a semicircle or a semi-ellipse. A maximum length Lmax of the light extraction patterns LEP in the third direction DR3 may be approximately 100 nm. Further, the distance between adjacent light extraction patterns LEP may be approximately 100 nm or less.

An electron-blocking layer may be located between the first semiconductor layer SEM1 and the active layer MQW. The electron-blocking layer may be a layer to suppress or prevent too many electrons from flowing into the active layer MQW. For example, the electron-blocking layer may be aluminum gallium nitride (AlGaN) or p-type aluminum gallium nitride (AlGaN) doped with p-type magnesium (Mg). The electron-blocking layer may be omitted.

A superlattice layer may be located between the active layer MQW and the second semiconductor layer SEM2. The superlattice layer may be a layer for relieving stress between the second semiconductor layer SEM2 and the active layer MQW. For example, the superlattice layer may be aluminum gallium nitride (AlGaN) or p-type aluminum gallium nitride (AlGaN) doped with p-type magnesium (Mg). The superlattice layer may be omitted.

The protective film INS may be a film for protecting the bottom surface and the side surface of the light-emitting element LE. The protective film INS may be located on the bottom surface and the side surface of the conductive layer E1 and the side surface of the semiconductor stack STC. For example, the protective film INS may be located on the bottom surface and the side surface of the conductive layer E1, the side surface of the first semiconductor layer SEM1, the side surface of the active layer MQW, and the side surface of the second semiconductor layer SEM2. The protective film INS may include an inorganic film, such as silicon nitride (SiNₓ), silicon oxide nitride (SiON), silicon oxide (SiOₓ), titanium oxide (TiOₓ), or aluminum oxide (AlOₓ). The protective film INS is preferably located from one end to the other end of the side of the light-emitting element LE, but it may be located slightly apart from one end due to process error.

A hole LEH may penetrate the conductive layer E1, the first semiconductor layer SEM1, and the active layer MQW of the light-emitting element LE to expose the second semiconductor layer SEM2. The hole LEH may have a rectangular planar shape, but the embodiments of the present disclosure are not limited thereto. For example, the hole LEH may have a polygonal planar shape, such as a circle, oval, or square.

In addition, the protective film INS may be located on the sidewall of the conductive layer E1 exposed in the hole LEH, the sidewall of the first semiconductor layer SEM1, and the sidewall of the active layer MQW. The protective film INS may not cover the second semiconductor layer SEM2 in the hole LEH. Therefore, the second semiconductor layer SEM2 may be exposed without being covered by the protective film INS (e.g., may be exposed through a hole defined by the protective film INS).

The first contact electrode CTE1 may be located on at least one side surface of the semiconductor stack STC, and at least one side surface and the bottom surface of the conductive layer E1. The first contact electrode CTE1 may be located on the bottom surface of the conductive layer E1 exposed without being covered by the protective film INS (e.g., exposed through a hole defined by the protective film INS). Therefore, the first contact electrode CTE1 may be electrically connected to the conductive layer E1.

The second contact electrode CTE2 may be located on at least one side of the semiconductor stack STC and at least one side and the bottom surface of the conductive layer E1. At this time, the first contact electrode CTE1 may be located on the first side of the semiconductor stack STC and the first side of the conductive layer E1, while the second contact electrode CTE2 may be located on the second side of the semiconductor stack STC and the second side of the conductive layer E1.

The second contact electrode CTE2 may be located on the protective film INS located in the hole LEH and in the second semiconductor layer SEM2 exposed without being covered by the protective film INS in the hole LEH. Therefore, the second contact electrode CTE2 may be electrically connected to the second semiconductor layer SEM2 in the hole LEH.

The first contact electrode CTE1 and the second contact electrode CTE2 may be located on at least a portion of a side surface of the semiconductor stack STC. At least an area adjacent to a top surface of the semiconductor stack STC among the side surfaces of the semiconductor stack STC may be exposed without being covered by the first contact electrode CTE1 and the second contact electrode CTE2. For example, the first contact electrode CTE1 and the second contact electrode CTE2 are spaced apart from the top surface of the semiconductor stack STC in the third direction DR3. The first contact electrode CTE1 and the second contact electrode CTE2 may be lower than at least one end of the protective film INS. For example, a distance from the first contact electrode CTE1 and the second contact electrode CTE2 to the top surface of the semiconductor stack STC may be greater than a distance between the protective film INS and the top surface of the semiconductor stack STC.

The first contact electrode CTE1 and the second contact electrode CTE2 may include one of molybdenum (Mo), aluminum (Al), chromium (Cr), gold (Au), titanium (Ti), nickel (Ni), neodymium (Nd), or copper (Cu). For example, the first contact electrode CTE1 and the second contact electrode CTE2 may be formed as a two-layer structure of chromium (Cr) and gold (Au), a three-layer structure of titanium (Ti), aluminum (Al), and titanium (Ti), or a three-layer structure of indium tin oxide (ITO), silver (Ag), and indium tin oxide (ITO) to increase reflectivity.

Each of the first contact electrode CTE1 and the second contact electrode CTE2 may be located on three sides of the semiconductor stack STC. For example, when the semiconductor stack STC includes first to fourth sides, the first contact electrode CTE1 may be located on the first side, the second side, and the third side, and the second contact electrode CTE2 may be located on the second side, the third side, and the fourth side.

The connection electrodes BE1 and BE2 electrically connect the light-emitting element LE and the pixel electrode layer.

Further, the first connection electrode BE1 may be located on the top surface of the organic layer 210 and the first contact electrode CTE1.

The first connection electrode BE1 may include a first sub-connection electrode BE11, and a second sub-connection electrode BE12 located on the first sub-connection electrode BE11. The first sub-connection electrode BE11 and the second sub-connection electrode BE12 may include the same material or different materials. Each of the first sub-connection electrode BE11 and the second sub-connection electrode BE12 may include one of molybdenum (Mo), aluminum (Al), chromium (Cr), gold (Au), titanium (Ti), nickel (Ni), neodymium (Nd), or copper (Cu). Alternatively, each of the first sub-connection electrode BE11 and the second sub-connection electrode BE12 may be made of a transparent conductive material (TCO), such as indium tin oxide (ITO) and indium zinc oxide (IZO).

The second connection electrode BE2 connects the second contact electrode CTE2 of the light-emitting element LE and the common electrode CE1 and CE2. The second connection electrode BE2 may be connected to the common electrode CE1 and CE2 exposed through a second connection hole BH2 penetrating the organic layer 210. Further, in one or more embodiments, the second connection electrode BE2 may be located on the top surface of the organic layer 210 and the second contact electrode CTE2.

The second connection electrode BE2 may include a third sub-connection electrode BE21, and a fourth sub-connection electrode BE22 located on the third sub-connection electrode BE21. The third sub-connection electrode BE21 and the fourth sub-connection electrode BE22 may include the same material, or may include different materials. Each of the third sub-connection electrode BE21 and the fourth sub-connection electrode BE22 may include any one of molybdenum (Mo), aluminum (Al), chromium (Cr), gold (Au), titanium (Ti), nickel (Ni), neodymium (Nd), or copper (Cu). Alternatively, each of the third sub-connection electrode BE21 and the fourth sub-connection electrode BE22 may be made of a transparent conductive material (TCO), such as indium tin oxide (ITO) and indium zinc oxide (IZO).

The conductive layer E1 of the light-emitting element LE may be connected to the pixel electrode PXE1 and PXE2 through the first contact electrode CTE1 and the first connection electrode BE1. Further, the second semiconductor layer SEM2 of the light-emitting element LE may be connected to the common electrode CE1 and CE2 through the second contact electrode CTE2 and the second connection electrode BE2 formed in the hole LEH.

In addition, an area adjacent to the top surface of the semiconductor stack STC on each of the side surfaces of the semiconductor stack STC may be exposed without being covered by the first connection electrode BE1 or the second connection electrode BE2.

The second organic film 211 may cover a portion of the side surfaces of the plurality of light-emitting elements LE. Further, the second organic film 211 may cover the first connection electrode BE1 and the second connection electrode BE2.

The third organic film 212 may be located on the second organic film 211. The third organic film 212 may cover another portion of the side surfaces of each of the plurality of light-emitting elements LE. The third organic film 212 may be located on the protective film INS, the first connection electrode BE1, and the second connection electrode BE2 that are not covered by the second organic film 211, as shown in FIG. 7, but the present disclosure is not limited thereto. The top surface of each of the plurality of light-emitting elements LE may be exposed without being covered by the third organic film 212. The second organic film 211 and the third organic film 212 are layers for flattening the steps caused by the plurality of light-emitting elements LE. When the height of the second organic film 211 is located to cover most of the side surfaces of each of the plurality of light-emitting elements LE, the third organic film 212 may be omitted.

The second organic film 211 and the third organic film 212 may include an organic film, such as an acrylic resin, an epoxy resin, a phenolic resin, a polyamide resin, or a polyimide resin. The first capping layer CAP1 may be located on the third organic film 212 and the light-emitting element LE.

The second organic film 211 and the third organic film 212 may include an organic film, such as an acrylic resin, an epoxy resin, a phenolic resin, a polyamide resin, a polyimide resin, or the like.

The first capping layer CAP1 may be located on the third organic film 212 and the light-emitting element LE.

A light-blocking layer BM, a first light conversion layer QDL1, a second light conversion layer QDL2, and a light transmission layer TPL may be located on the first capping layer CAP1. The first light conversion layer QDL1, the second light conversion layer QDL2, and the light transmission layer TPL may be formed by the compartments the light-blocking layer BM. Therefore, the first light conversion layer QDL1 may be located on the first capping layer CAP1 in the first sub-pixel SPX1, the second light conversion layer QDL2 may be located on the first capping layer CAP1 in the second sub-pixel SPX2, and the light transmission layer TPL may be located on the first capping layer CAP1 in the third sub-pixel SPX3. The light-blocking layer BM may not overlap the plurality of light-emitting elements LE in the third direction DR3.

The first light conversion layer QDL1 may convert a portion of the third light (e.g., light in the blue wavelength band) incident from the light-emitting element LE into first light (e.g., light in the red wavelength band). The first light conversion layer QDL1 may include a first base resin BRS1 and a first wavelength conversion particle WCP1. The first base resin BRS1 may include a light-transmitting organic material. The first wavelength conversion particle WCP1 may convert a portion of the third light (e.g., light in the blue wavelength band) incident from the light-emitting element LE into first light (e.g., light in the red wavelength band).

The second light conversion layer QDL2 may convert a portion of the third light (e.g., light in the blue wavelength band) incident from the light-emitting element LE into second light (e.g., light in the green wavelength band). The second light conversion layer QDL2 may include a second base resin BRS2 and a second wavelength conversion particle WCP2. The second base resin BRS2 may include a light-transmitting organic material. The second wavelength conversion particle WCP2 may convert a portion of the third light (e.g., light in the blue wavelength band) incident from the light-emitting element LE into second light (e.g., light in the green wavelength band).

The light transmission layer TPL may include a light-transmitting organic material.

For example, the first base resin BRS1, the second base resin BRS2, and the light transmission layer TPL may include an epoxy-based resin, an acrylic-based resin, a cado-based resin, or an imide-based resin. The first and second wavelength conversion particles WCP1 and WCP2 may be quantum dots (QD), quantum rods, fluorescent materials, or phosphorescent materials.

The light-blocking layer BM may include a first light-blocking layer BM1 and a second light-blocking layer BM2 that are sequentially stacked. A length of the first light-blocking layer BM1 in the first direction DR1 or a length of the second direction DR2 may be greater than a length of the second light-blocking layer BM2 in the first direction DR1 or a length of the second direction DR2 of the second light-blocking layer BM2. The first light-blocking layer BM1 and the second light-blocking layer BM2 may include an organic film, such as an acrylic resin, an epoxy resin, a phenolic resin, a polyamide resin, a polyimide resin, or the like. The first light-blocking layer BM1 and the second light-blocking layer BM2 may include a light-blocking material to reduce or prevent an amount of light from the light-emitting element LE of one sub-pixel from proceeding to the neighboring sub-pixel. For example, the first light-blocking layer BM1 and the second light-blocking layer BM2 may include an inorganic black pigment, such as carbon black or an organic black pigment.

The second capping layer CAP2 may be located on the first capping layer CAP1 and the light-blocking layer BM. The second capping layer CAP2 may be located on the side and top surfaces of the light-blocking layer BM. That is, the second capping layer CAP2 may be located on the side of the first light-blocking layer BM1 and the side and top surfaces of the second light-blocking layer BM2.

The reflective film RF may be located between the light-blocking layer BM and the first light conversion layer QDL1, between the light-blocking layer BM and the second light conversion layer QDL2, and between the light-blocking layer BM and the light transmission layer TPL. The reflective film RF may be located on a second capture layer CAP2 located on the side of the first light-blocking layer BM1 and the side of the second light-blocking layer BM2. The reflective film RF serves to reflect light traveling in the lateral direction from the first light conversion layer QDL1, the second light conversion layer QDL2, and the light transmission layer TPL.

The reflective film RF may include a highly reflective metal material, such as aluminum (Al). The thickness of the reflective film RF may be approximately 0.1 [symbol] .

Alternatively, the reflective layer RF2 may include a first layer and a second layer of M (M is an integer of 2 or more) pairs having different refractive indices to serve as Distributed Bragg Reflectors (DBR). In this case, M first layers and M second layers may be arranged alternately. The first layer and the second layer may include an inorganic film, for example, silicon nitride (SiNₓ), silicon oxide (SiON), silicon oxide (SiOₓ), titanium oxide (TiOₓ), or aluminum oxide (AlOₓ).

The third capping layer CAP3 may be located on the second capping layer CAP2, the first light conversion layer QDL1, the second light conversion layer QDL2, and the light transmission layer TPL.

The first capping layer CAP1, the second capping layer CAP2, and the third capping layer CAP3 may include an inorganic film, for example, silicon nitride (SiNₓ), silicon oxide (SiON), silicon oxide (SiOₓ), titanium oxide (TiOₓ), or aluminum oxide (AlOₓ). The first light conversion layer QDL1, the second capping layer CAP2, and the third capping layer CAP3 may be encapsulated by the first capture layer CAP1, the second capping layer CAP2, and the third capping layer CAP3.

A fourth organic film 213 may be located on the second capping layer CAP2. A plurality of color filters CF1, CF2, and CF3 may be located on the fourth organic film 213. The plurality of color filters CF1, CF2, and CF3 may include first color filters CF1, second color filters CF2, and third color filters CF3.

The first color filter CF1 located in the first sub-pixel SPX1 may transmit the first light (e.g., light in the red wavelength band) and absorb or block the third light (e.g., light in the blue wavelength band). Therefore, the first color filter CF1 may transmit the first light (e.g., light in the red wavelength band) that has been converted by the first light conversion layer QDL1 among the third light (e.g., light in the blue wavelength band) emitted from the light-emitting element LE and absorb or block the third light (e.g., light in the blue wavelength band) that has not been converted by the first light conversion layer QDL1. Accordingly, the first sub-pixel SPX1 may emit the first light (e.g., light in the red wavelength band).

The second color filter CF2 located in the second sub-pixel SPX2 may transmit the second light (e.g., light in the green wavelength band) and absorb or block the third light (e.g., light in the blue wavelength band). Therefore, the second color filter CF2 may transmit the second light (e.g., light in the green wavelength band) that has been converted by the first light conversion layer QDL1 among the third light (e.g., light in the blue wavelength band) emitted from the light-emitting element LE and absorb or block the third light (e.g., light in the blue wavelength band) that has not been converted by the first light conversion layer QDL1. Accordingly, the second sub-pixel SPX2 may emit the second light (e.g., light in the green wavelength band).

The third color filter CF3 located in the third sub-pixel SPX3 may transmit the third light (e.g., light in the blue wavelength band). Therefore, the third color filter CF3 may transmit the third light (e.g., light in the blue wavelength band) emitted from the light-emitting element LE passing through the light transmission layer TPL. Accordingly, the third sub-pixel SPX3 may emit the third light (e.g., light in the blue wavelength band).

The first color filter CF1, the second color filter CF2, and the third color filter CF3 overlapping in the third direction DR3 may overlap with the light-blocking layer BM in the third direction DR3.

A fifth organic film 214 for planarization may be located on the plurality of color filters CF1, CF2, and CF3.

The fourth organic film 213 and the fifth organic film 214 may include an acrylic resin, an epoxy resin, a phenolic resin, a polyamide resin, a polyimide resin, or the like.

Referring to FIGS. 6 and 8, a repair light-emitting element RLE is shown as being located in the third sub-pixel SPX3 but is not limited thereto. The repair light-emitting element RLE may be transferred to a location where the light-emitting element LE has been removed due to a defect or the like. A repair material (e.g., a bonding material, or a repair bonding material) RM is located between the repair light-emitting element RLE and the pixel electrode layer to transfer the repair light-emitting element RLE to a location where the light-emitting element LE has been removed. The repair light-emitting element RLE has the same structure as the light-emitting element LE described in FIG. 7. Accordingly, the repair light-emitting element RLE may include a conductive layer E1, a semiconductor stack STC, a first contact electrode CTE1, a second contact electrode CTE2, and a protective film INS. The detailed description of the conductive layer E1, the semiconductor stack STC, the first contact electrode CTE1, the second contact electrode CTE2, and the protective film INS is redundant and therefore will not be repeated.

The organic layer 210 may be partially removed when the defective light-emitting element LE is removed, so that only a portion may remain between the pixel electrode PXE3 and the common electrode CE3. The organic layer 210 remaining in this way is not located on the pixel electrode PXE3 and the common electrode CE3.

The repair material RM1 and RM2 is located between the pixel electrode PXE3 and the common electrode CE3. For example, a first repair material RM1 may be located between the pixel electrode PXE3 and the first contact electrode CTE1. A second repair material RM2 may be located between the common electrode CE3 and the second contact electrode CTE2. The second repair material RM2 may fill a hole LEH exposing the second semiconductor layer SEM2. The second repair material RM2 may be filled higher than the active layer MQW in the hole LEH (e.g., may have a height that is greater than that of the active layer MQW), but is not limited thereto.

The volume of the second repair material RM2 is larger than the volume of the first repair material RM1. For example, the volume of the second repair material RM2 may range from about 1.1 to about 3.0 relative to the volume of the first repair material RM1.

The repair material RM1 and RM2 may use conductive ink, conductive paste, conductive photoresist, or the like. For example, the repair material RM1 and RM2 may be an organic material including conductive particles, such as a conductive metal or carbon black. The conductive metal may be particles formed of, for example, silver (Ag), aluminum (Al), chromium (Cr), gold (Au), titanium (Ti), copper (Cu), and/or the like but is not limited thereto.

According to one or more embodiments, by applying the volume of the second repair material RM2 and the volume of the first repair material RM1 differently, the risk of resistance increase between the second repair material RM2 provided with the hole LEH and the light-emitting element LE may be reduced or minimized, while the risk of short circuit defects between the pixel electrode PXE3 and the common electrode CE3 may be reduced or minimized.

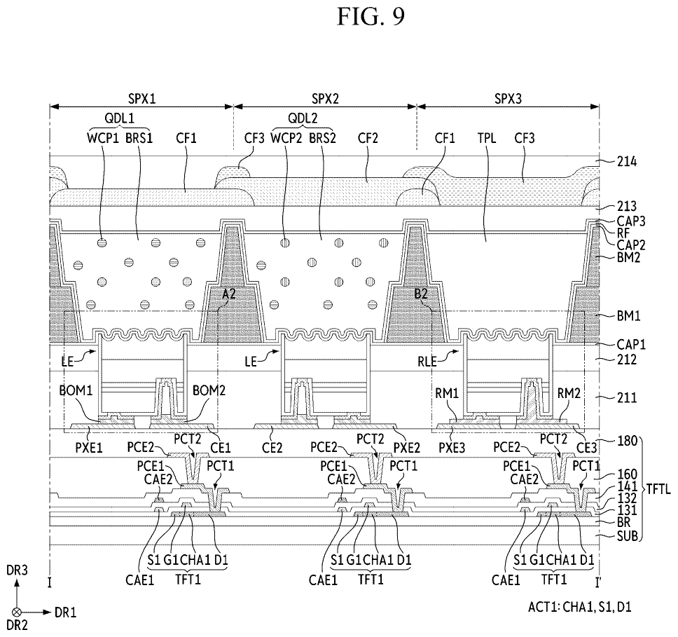

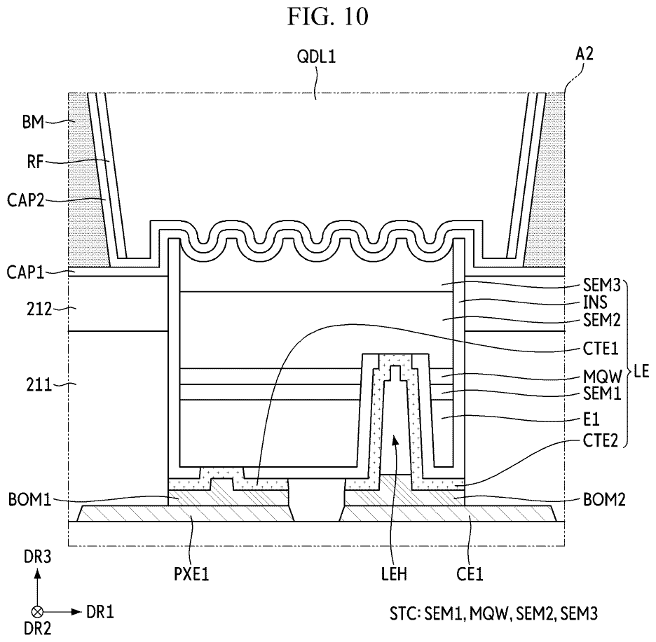

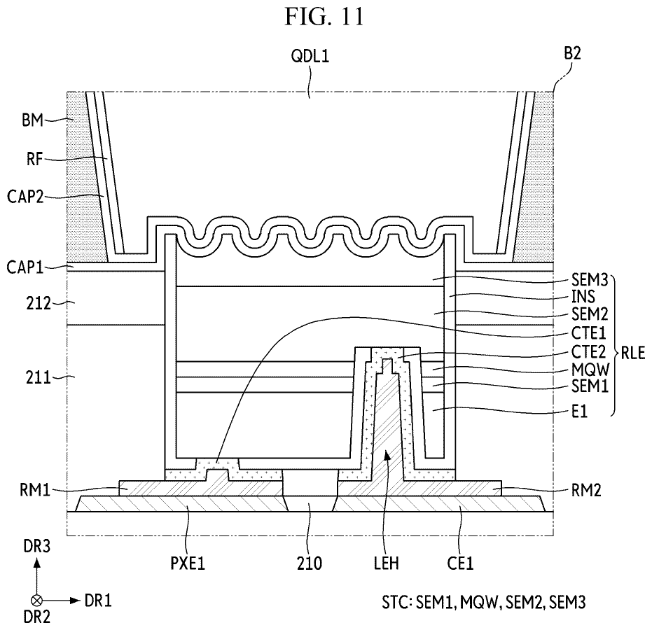

FIG. 9 is a cross-sectional view illustrating another example of a cross-section of the display panel corresponding to the line I-I′ of FIG. 5. FIG. 10 is a cross-sectional view illustrating another example of area A2 of FIG. 9 in detail. FIG. 11 is a cross-sectional view illustrating the repair light-emitting element and repair material of FIG. 9.

The embodiments of FIGS. 9 to 11 differ from the embodiments of FIGS. 6 to 8 in that the light-emitting element LE is bonded to the pixel electrode layer with a bonding metal BOM instead of an organic layer 210, and the contact electrode CTE is not located on the side of the semiconductor stack STC. In FIGS. 9 to 11, descriptions that overlap with the embodiments of FIGS. 6 to 8 will be omitted, and differences from the embodiments of FIGS. 6 to 8 will be mainly described.

Referring to FIGS. 9 and 10, bonding metals BOM1 and BOM2 may be located between the light-emitting element LE and the pixel electrode layer.

A first bonding metal BOM1 may be located on the pixel electrodes PXE1 and PXE2, and a second bonding metal BOM2 may be located on the common electrodes CE1 and CE2. A first contact electrode CTE1 may be located on a first bonding metal BOM1, and a second contact electrode CTE2 may be located on a second bonding metal BOM2.

The first contact electrode CTE1 may be located on one surface of a semiconductor stack STC. The first contact electrode CTE1 may be located on a bottom surface of a conductive layer E1 that is exposed and not covered by a protective film INS. Therefore, the first contact electrode CTE1 may be electrically connected to the conductive layer E1.

The second contact electrode CTE2 may be located on one surface of the semiconductor stack STC similarly to the first contact electrode CTE1 (e.g., on a same surface of the semiconductor stack STC), although the second contact electrode CTE2 may be spaced apart from the first contact electrode CTE1.

The second contact electrode CTE2 may be located on (e.g., may contact) the protective layer INS located in the hole LEH and the second semiconductor layer SEM2 exposed without being covered by the protective layer INS in the hole LEH. Therefore, the second contact electrode CTE2 may be electrically connected to the second semiconductor layer SEM2 in the hole LEH.

The bonding metal BOM1 and BOM2 may include at least one of gold (Au), copper (Cu), aluminum (Al), or tin (Sn), or may include a transparent conductive oxide, such as indium tin oxide (ITO) or indium zinc oxide (IZO). Alternatively, the connection electrode 126 may include a first layer including one of gold (Au), copper (Cu), aluminum (Al), or tin (Sn), and a second layer including another one of gold (Au), copper (Cu), aluminum (Al), or tin (Sn).

Referring to FIG. 9, although it is illustrated that the repair light-emitting element RLE is located in the third sub-pixel SPX3, it is not limited thereto. The one or more embodiments corresponding to FIG. 10 is different from FIG. 8 in that the organic layer 210 is not located.

The bonding metals BOM1 and BOM2 of FIGS. 9 and 10 have lower melting points than the repair materials RM1 and RM2, and thus may be referred to as low-melting-point bonding metals BOM.

The repair materials RM1 and RM2 may have electrical characteristics that are somewhat lower than the low-melting-point bonding metals BOM1 and BOM2. Accordingly, the repair materials RM1 and RM2 may contribute to improving the electrical characteristics by filling the hole LEH exposing the second semiconductor layer SEM2.

In addition, the repair materials RM1 and RM2 may have a higher melting point than the low-melting-point bonding metal generally used for light-emitting element LE transfer. In the case of the low-melting-point bonding metal, it may be advantageous or suitable for bonding multiple light-emitting elements at once over a large area, but it is difficult to apply to the repair process for selectively re-bonding fine-sized light-emitting elements LE.

Because the repair materials RM1 and RM2 uses conductive ink, conductive paste, conductive photoresist, etc., it is easy to place a desired amount in a local area, so it is advantageous for application to the repair process.

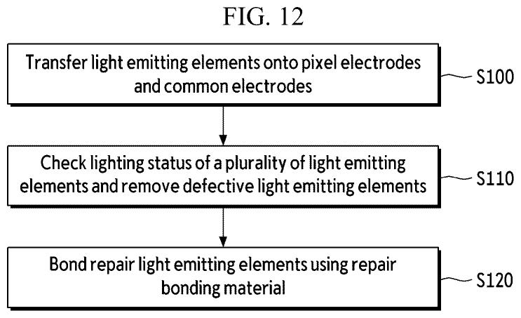

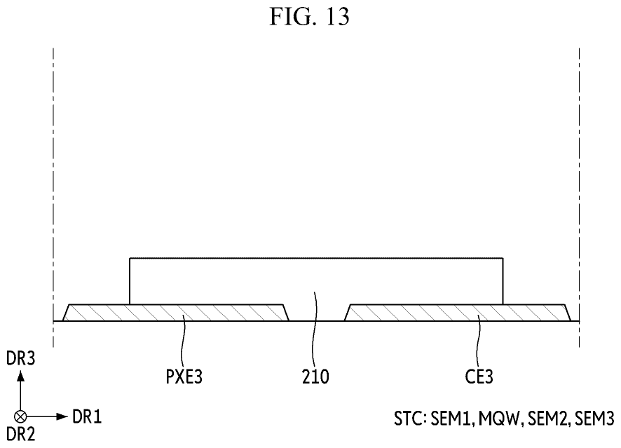

FIG. 12 is a flowchart illustrating a method of manufacturing a display device according to one or more embodiments. FIGS. 13 to 19 are example drawings to illustrate a method of manufacturing a display device according to one or more embodiments.

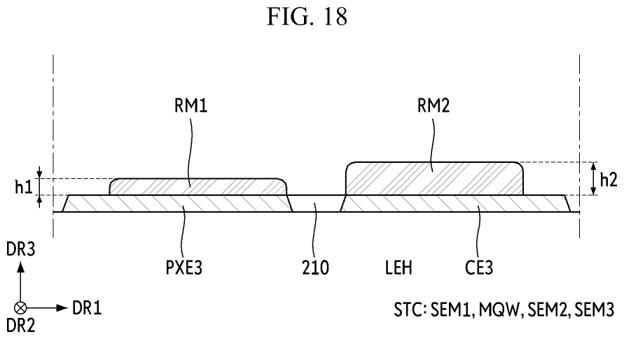

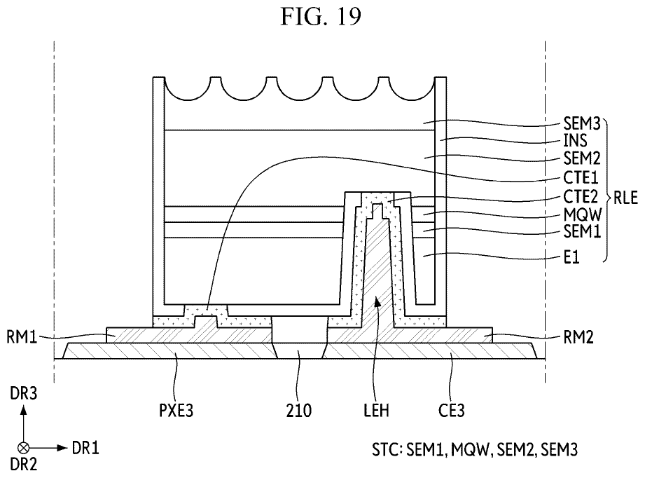

Hereinafter, a method for manufacturing a display device according to one or more embodiments will be described in detail by connecting FIG. 12 with FIG. 13 to FIG. 19. FIG. 13 to FIG. 16, FIG. 18, and FIG. 19 illustrate a display device according to one or more embodiments of FIG. 8 for convenience of explanation.

First, a plurality of light-emitting elements LE are transferred onto the pixel electrode PXE3 and the common electrode CE3 (S100 in FIG. 12).

Referring to FIG. 13, an organic layer 210 is formed on the pixel electrode PXE3 and the common electrode CE3. The organic layer 210 may cover at least a portion of the pixel electrode PXE3 and the common electrode CE3 on one surface of the substrate SUB. If the organic layer 210 is a photosensitive organic film, such as a photoresist, the organic layer 210 may be soft baked at a first temperature.

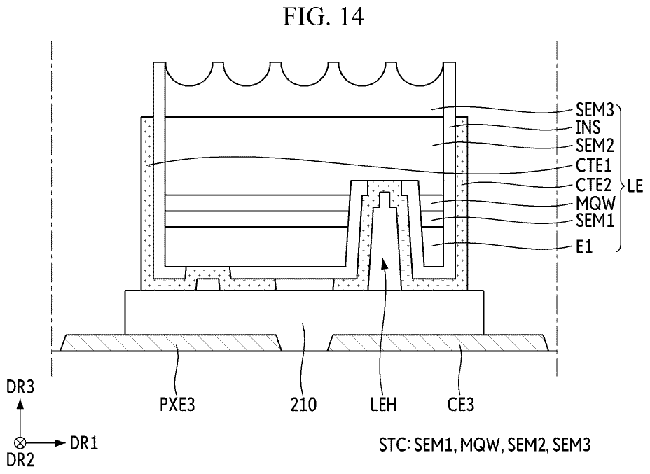

Referring to FIG. 14, a plurality of light-emitting elements LE are transferred to the organic layer 210. Each of the plurality of light-emitting elements LE may be formed by growing on a semiconductor substrate, such as a silicon substrate or a sapphire substrate. The plurality of light-emitting elements LE may be transferred directly from the semiconductor substrate onto the pixel electrodes PXE3 of the display panel 100. Alternatively, the plurality of light-emitting elements LE may be transferred onto the pixel electrodes PXE3 of the display panel 100 through an electrostatic method using an electrostatic head or a stamp method using an elastic polymer material, such as PDMS or silicon as a transfer substrate.

After the plurality of light-emitting elements LE are located on each organic layer 210, the light-emitting elements LE are thermally compressed onto the organic layer 210. Accordingly, at least a portion of the light-emitting elements LE may be temporarily fixed by being embedded in the organic layer 210. When the fluidity of the organic layer 210 is small or the organic layer 210 is solid, the depth at which the light-emitting element LE is inserted or embedded in the organic layer 210 may be very small, or the light-emitting element LE may be located on the organic layer 210 without being inserted or embedded in the organic layer 210. Then, the organic layer 210 may be completely cured at a second temperature that is higher than the first temperature. The first temperature may be approximately 100 degrees, and the second temperature may be approximately 230 degrees, but the embodiments of the present disclosure are not limited thereto. In addition, the process of completely curing the organic layer 210 at the second temperature may be performed for approximately 30 minutes.

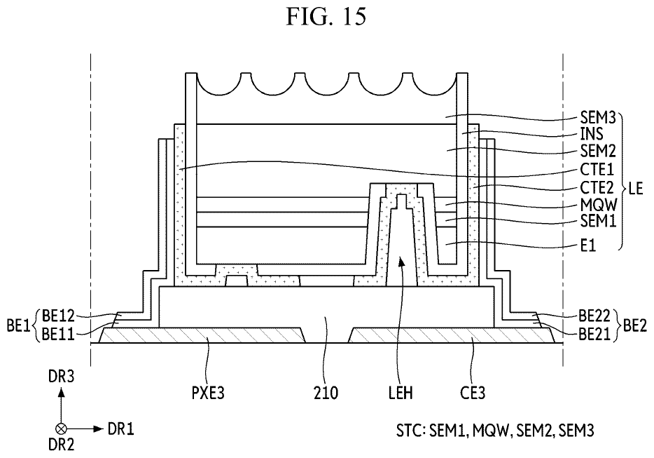

Thereafter, referring to FIG. 15, first connection electrodes BE1 for connecting the first contact electrode CTE1 of the light-emitting element LE and the pixel electrode PXE3, and second connection electrodes BE2 for connecting the second contact electrode CTE2 and the common electrode CE3, are formed. For example, a connection electrode material layer is deposited to cover the side surface of the light-emitting element LE. A portion of the connection electrode material layer is patterned by photoresist and etched to form the first connection electrode BE1 and the second connection electrode BE2 on the side surface of the light-emitting element LE.

The first connection electrodes BE1 may directly contact the first contact electrode CTE1 on the side surface of the light-emitting element LE, and may directly contact the pixel electrode PXE3 (e.g., an upper surface of the pixel electrode PXE3). The second connection electrodes BE2 may directly contact the second contact electrode CTE2 on the side surface of the light-emitting element LE, and may directly contact the common electrode CE3 (e.g., an upper surface of the common electrode CE3).

According to one or more other embodiments, in the display device described with reference to FIG. 10, the light-emitting element LE may be bonded to the pixel electrode PXE3 and the common electrode CE3 using a bonding metal without an organic layer 210.

Second, the lighting status of a plurality of light-emitting elements LE is inspected, and a defective light-emitting element LE is removed (S110 in FIG. 12).

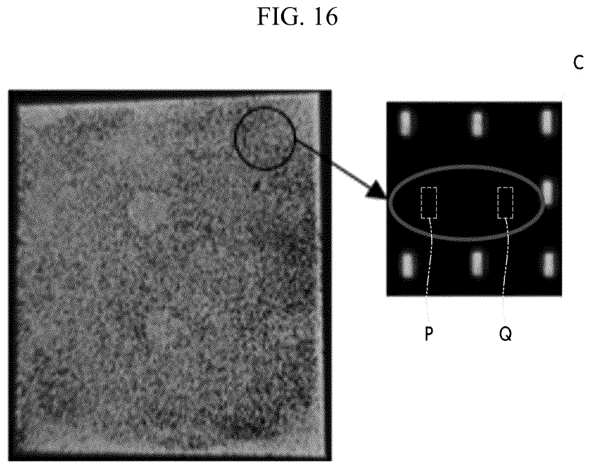

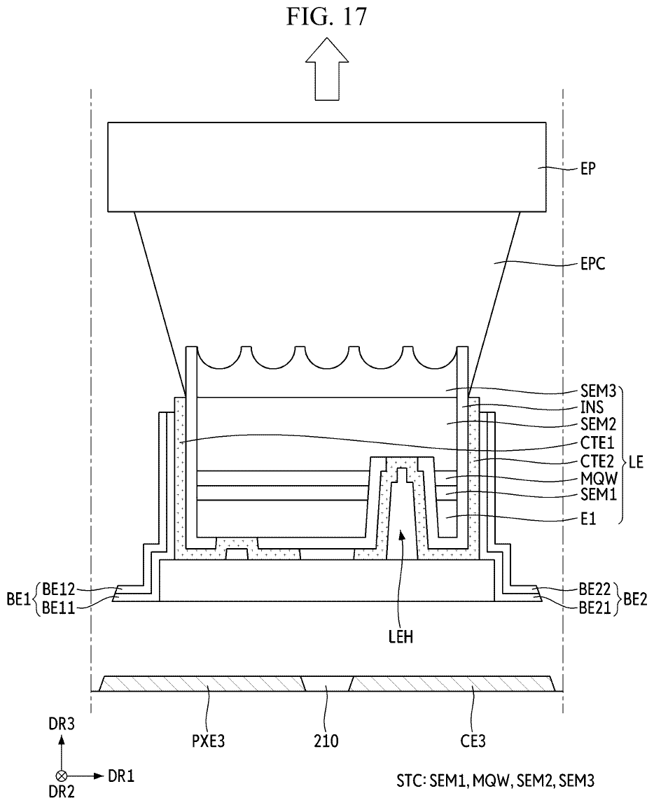

Referring to FIGS. 16 and 17, a photoluminescence test and/or an electroluminescence test may be performed to detect whether a defective light-emitting element LE exists or not. For example, part C of FIG. 16 shows two defective light-emitting elements identified at corresponding positions P and Q, as an example. After identifying the corresponding positions of the defective light-emitting elements, a repair process will be performed to replace the defective light-emitting elements with new light-emitting elements.

A first equipment EP may be employed to remove the defective light-emitting elements from the corresponding positions P and Q. The first equipment EP may absorb and hold the defective light-emitting element by vacuum pressure. For this purpose, the first equipment EP may have one vacuum chuck EPC.

In some embodiments, the first equipment EP may include an electrostatic device, an electromagnetic device, or an adhesive stamp to replace the vacuum chuck EPC. In one or more embodiments, because the first equipment EP has one vacuum chuck EPC, one defective light-emitting element is removed in one removal procedure. In other embodiments, two or more defective light-emitting elements may be removed concurrently or substantially simultaneously, which means that both defective light-emitting elements at corresponding positions P and Q may be removed together.

Third, the repair light-emitting element RLE is bonded using a repair materials RM1 and RM2 (S120 in FIG. 12).

Referring to FIG. 18, a first repair material RM1 and a second repair material RM2 are respectively applied on the pixel electrode PXE3 and on the common electrode CE3 from which the defective light-emitting element LE has been removed.

The first repair material RM1 and the second repair material RM2 may be a conductive ink, a conductive paste, or a conductive photoresist, and thus may be applied to a local area by a dispenser, an inkjet, or the like.

The amount of the second repair material RM2 applied on the common electrode CE3 is made different from the amount of the first repair material RM1 applied on the pixel electrode PXE3. By using a method, such as an inkjet, the application amounts of the repair material RM1 and RM2 on the pixel electrode PXE3 and the common electrode CE3 may be made differently without an additional process. On the other hand, an additional process may be required to form the bonding metal or the like with different thicknesses on the pixel electrode PXE3 and the common electrode CE3.

The thickness, or height, h1 of the first repair material RM1 applied on the pixel electrode PXE3 may be less than the thickness/height h2 of the second repair material RM2. For example, the amount of the second repair material RM2 applied on the common electrode CE3 may be about 1.1 to about 3.0 times more than the amount of the first repair material RM1 applied on the pixel electrode PXE3. Accordingly, the volume of the second repair material RM2 may have a range of about 1.1 to about 3.0 relative to the volume of the first repair material RM1.

If the amount of the first repair material RM1 is applied in a relatively large amount (e.g., as much as the amount of the second repair material RM2), the first repair material RM1 and the second repair material RM2 may be connected to each other, resulting in a short circuit risk.

In addition, if the amount of the second repair material RM2 is applied in a relatively small amount (e.g., as much as the amount of the first repair material RM1), the second repair material RM2 may not fill the hole LEH of the repair light-emitting element (RLE in FIG. 19), resulting in a risk of increased electrical resistance.

As shown in FIG. 19, the repair light-emitting element RLE is located on the first repair material RM1 and the second repair material RM2, and the repair light-emitting element RLE is bonded to the pixel electrode layer.

The first contact electrode CTE1 of the repair light-emitting element RLE may be located on the first repair material RM1, and the second contact electrode CTE2 of the repair light-emitting element RLE may be located on the second repair material RM2.

The second repair material RM2 may fill the hole LEH exposing the second semiconductor layer SEM2 of the light-emitting element LE. Accordingly, the contact resistance of the interface between the second repair material RM2 and the second semiconductor layer SEM2 may be adjusted.

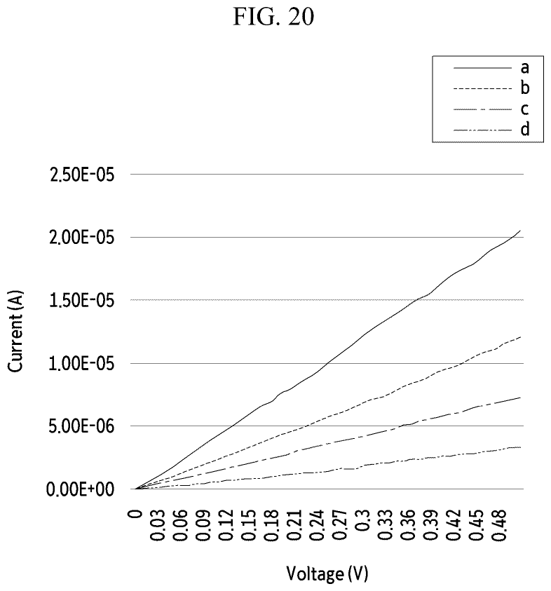

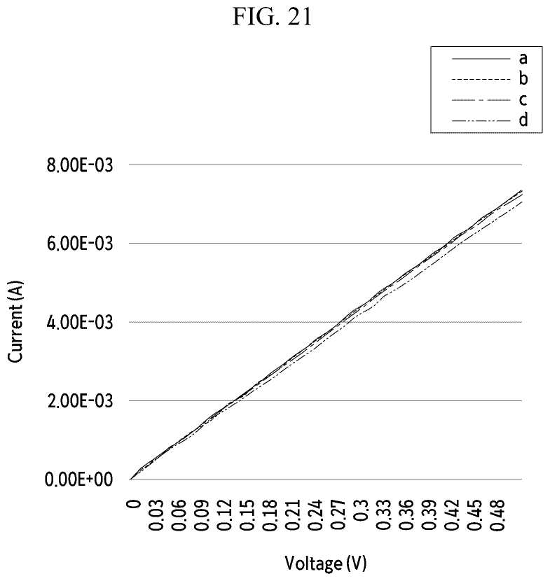

FIG. 20 is a graph illustrating the magnitude of current versus voltage of a light-emitting element bonded using a repair material according to one or more embodiments. FIG. 21 is a graph illustrating the magnitude of current versus voltage of a light-emitting element bonded using a conventional bonding metal.

In each of the graphs of FIG. 20 and FIG. 21, the electrical conductivity is shown for the contact ratio between the repair material and the light-emitting element.

For example, in the case of FIG. 20, ‘a’ represents the current for the voltage when the contact ratio between the repair bond and the light-emitting element is relatively large, and ‘d’ represents the current for the voltage when the contact ratio between the repair bond and the light-emitting element is the relatively small. In FIG. 20, ‘b’ represents the current for the voltage when the contact ratio between the repair bond and the light-emitting element is less than ‘a’ and greater than ‘c’, and ‘c’ represents the current for the voltage when the contact ratio between the repair bond and the light-emitting element is less than ‘b’ and greater than ‘d’. The larger the current for the voltage, the higher the electrical conductivity. Thus, in the case of the conservative repair material/bonding material, the electrical conductivity is greatly affected by the contact ratio between the repair material and the light-emitting element.

In FIG. 21, ‘a’ represents the current for the voltage when the contact ratio between the bonding metal and the light-emitting element is large, and ‘d’ represents the current for the voltage when the contact ratio between the bonding metal and the light-emitting element is the smallest. ‘b’ represents the current for the voltage when the contact ratio between the bonding metal and the light-emitting element is less than a and greater than ‘c’, and ‘c’ represents the current for the voltage when the contact ratio between the bonding metal and the light-emitting element is less than ‘b’ and greater than ‘d’. The higher the current for the voltage, the higher the electrical conductivity. Thus, in the case of the bonding metal, the electrical conductivity is not greatly affected by the contact ratio between the bonding metal and the light-emitting element.

Referring to FIGS. 20 and 21, the electrical conductivity of the repair material is greatly affected by the contact ratio than that of the bonding metal.

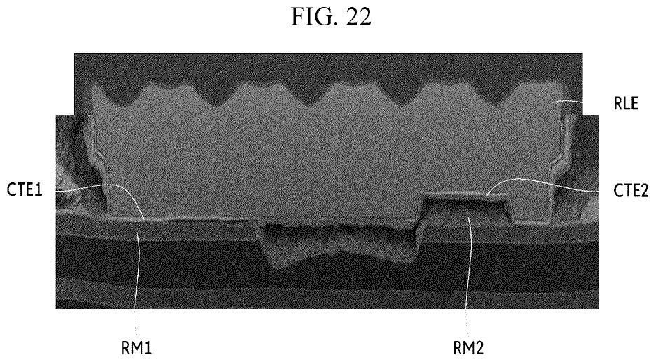

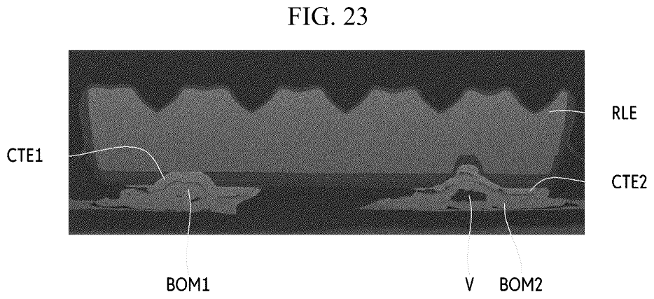

FIG. 22 is an image of a repair light-emitting element using a repair material according to one or more embodiments. FIG. 23 is an image of a repair light-emitting element using a conventional bonding metal.

Referring to FIG. 22, the repair material RM2 fills the inside of the hole LEH of the light-emitting element LE, showing a state in which the repair material is in full contact with the second contact electrode CTE2 without voids.

Referring to FIG. 23, when the bonding metal is filled to the inside of the hole LEH of the light-emitting element LE, there is a high probability that a void V will occur.

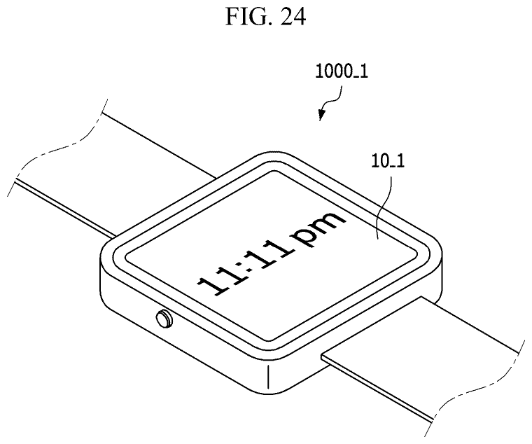

FIG. 24 is a view of a smart watch including a display device according to one or more embodiments.

Referring to FIG. 24, a display device 10_1 according to one or more embodiments may be applied to a smart watch 1000_1, which is one of smart devices.

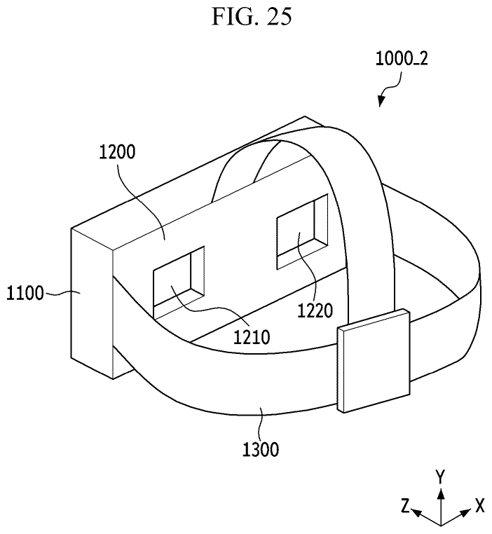

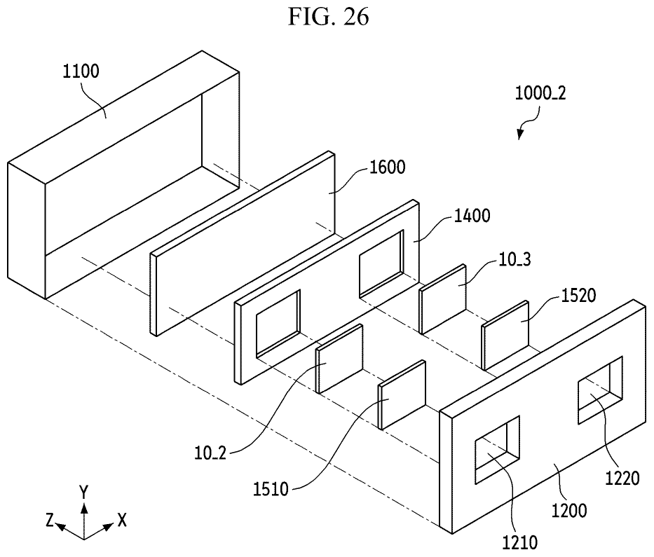

FIGS. 25 and 26 are views of a virtual reality (VR) device including a display device according to one or more embodiments.

Referring to FIGS. 25 and 26, a head-mounted display device 1000_2 according to one or more embodiments includes a first display device 10_2, a second display device 10_3, a display device housing 1100, a housing cover 1200, a first eyepiece 1210, a second eyepiece 1220, a head-mounted band 1300, a middle frame 1400, a first optical member 1510, a second optical member 1520, and a control circuit board 1600.

The first display device 10_2 provides an image to a user's left eye, and the second display device 10_3 provides an image to the user's right eye. Each of the first display device 10_2 and the second display device 10_3 is substantially the same as the display device 10 described with reference to FIGS. 1 and 2. Therefore, a description of the first display device 10_2 and the second display device 10_3 will be omitted.

The first optical member 1510 may be located between the first display device 10_2 and the first eyepiece 1210. The second optical member 1520 may be located between the second display device 10_3 and the second eyepiece 1220. Each of the first optical member 1510 and the second optical member 1520 may include at least one convex lens.

The middle frame 1400 may be located between the first display device 10_2 and the control circuit board 1600, and may be located between the second display device 10_3 and the control circuit board 1600. The middle frame 1400 supports and fixes the first display device 10_2, the second display device 10_3, and the control circuit board 1600.

The control circuit board 1600 may be located between the middle frame 1400 and the display device housing 1100. The control circuit board 1600 may be connected to the first display device 10_2 and the second display device 10_3 through a connector. The control circuit board 1600 may convert an image source received from the outside into digital video data DATA and transmit the digital video data DATA to the first display device 10_2 and the second display device 10_3 through the connector.

The control circuit board 1600 may transmit the digital video data DATA corresponding to a left image optimized for a user's left eye to the first display device 10_2, and may transmit the digital video data DATA corresponding to a right image optimized for the user's right eye to the second display device 10_3. Alternatively, the control circuit board 1600 may transmit the same digital video data DATA to the first display device 10_2 and the second display device 10_3.

The display device housing 1100 houses the first display device 10_2, the second display device 10_3, the middle frame 1400, the first optical member 1510, the second optical member 1520, and the control circuit board 1600. The housing cover 1200 is placed to cover an open surface of the display device housing 1100. The housing cover 1200 may include the first eyepiece 1210 on which a user's left eye is placed and the second eyepiece 1220 on which the user's right eye is placed. Although the first eyepiece 1210 and the second eyepiece 1220 are located separately in FIGS. 25 and 26, embodiments of the present specification are not limited thereto. The first eyepiece 1210 and the second eyepiece 1220 may also be combined into one.

The first eyepiece 1210 may be aligned with the first display device 10_2 and the first optical member 1510, and the second eyepiece 1220 may be aligned with the second display device 10_3 and the second optical member 1520. Therefore, a user can view an image of the first display device 10_2, which is enlarged as a virtual image by the first optical member 1510, through the first eyepiece 1210 and can view an image of the second display device 10_3, which is enlarged as a virtual image by the second optical member 1520, through the second eyepiece 1220.

The head-mounted band 1300 fixes the display device housing 1100 to a user's head so that the first eyepiece 1210 and the second eyepiece 1220 of the housing cover 1200 are kept placed on the user's left and right eyes, respectively. When the housing cover 1200 is implemented to be lightweight and small, the head-mounted display device 1000_2 may include an eyeglass frame as illustrated in FIG. 33 instead of the head-mounted band 1300.

In addition, the head-mounted display device 1000_2 may further include a battery for supplying power, an external memory slot for accommodating an external memory, and an external connection port and a wireless communication module for receiving an image source. The external connection port may be a universe serial bus (USB) terminal, a display port, or a high-definition multimedia interface (HDMI) terminal, and the wireless communication module may be a 5G communication module, a 4G communication module, a Wi-Fi module, or a Bluetooth module.

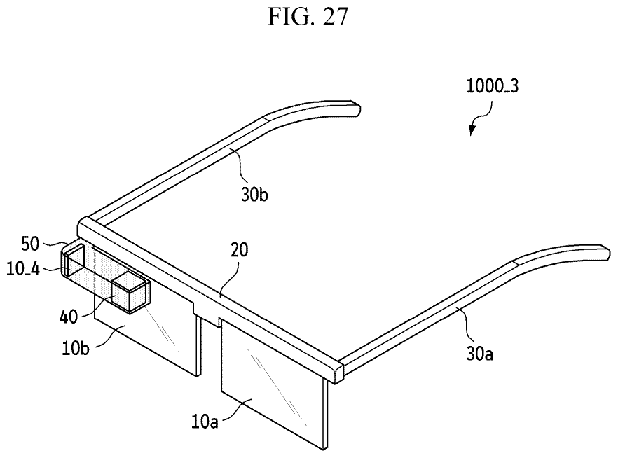

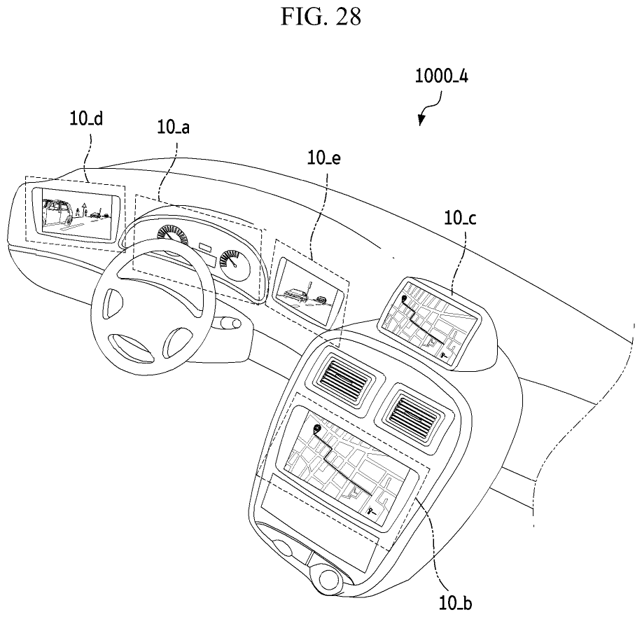

FIG. 27 is a view of a VR device including a display device according to one or more embodiments. FIG. 28 illustrates a VR device 1000_3 to which a display device 10_4 according to one or more embodiments has been applied.

Referring to FIG. 27, the VR device 1000_3 according to one or more embodiments may be a device in the form of glasses. The VR device 1000_3 may include the display device 10_4, a left lens 10a, a right lens 10b, a support frame 20, eyeglass frame legs 30a and 30b, a reflective member 40, and a display device housing 50.

In FIG. 27, a case where the VR device 1000_3 is a glasses-type display device including the eyeglass frame legs 30a and 30b is illustrated only as an example. That is, the VR device 1000_3 is not limited to the one illustrated in FIG. 30 and can be applied in various forms to various other electronic devices.

The display device housing 50 may include the display device 10_4 and the reflective member 40. An image displayed on the display device 10_4 may be reflected by the reflective member 40 and provided to a user's right eye through the right lens 10b. Accordingly, the user may view a VR image displayed on the display device 10_4 through the right eye.

Although the display device housing 50 is located at a right end of the support frame 20 in FIG. 27, embodiments of the present specification are not limited thereto. For example, the display device housing 50 may also be located at a left end of the support frame 20. In this case, an image displayed on the display device 10_4 may be reflected by the reflective member 40 and provided to the user's left eye through the left lens 10a. Accordingly, the user may view a VR image displayed on the display device 10_4 through the left eye. Alternatively, the display device housing 50 may be located at both the right end and the left end of the support frame 20. In this case, the user may view a VR image displayed on the display device 10_4 through both the left eye and the right eye.

FIG. 28 is a view illustrating a vehicle instrument cluster and center fascia including display devices according to one or more embodiments. FIG. 28 illustrates a vehicle to which display devices 10_a through 10_e according to one or more embodiments have been applied.

Referring to FIG. 28, the display devices 10_a through 10_c may be applied to an instrument cluster of the vehicle, a center fascia of the vehicle, or a center information display (CID) located on a dashboard of the vehicle. In addition, the display devices 10_d and 10_e may be applied to room mirror displays that replace side mirrors of the vehicle.

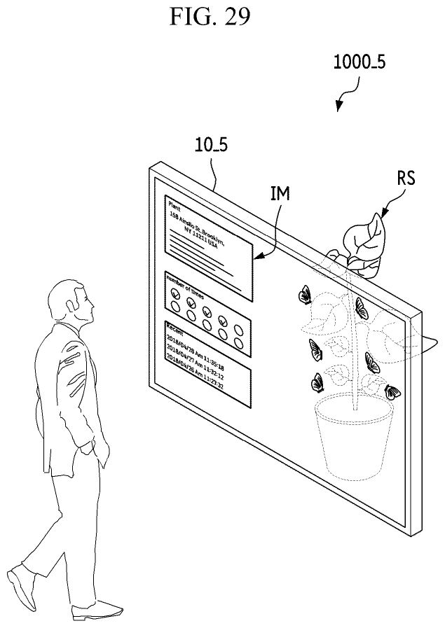

FIG. 29 is a view of a transparent display device including a display device according to one or more embodiments.

Referring to FIG. 29, a display device 10_5 according to one or more embodiments may be applied to a transparent display device. The transparent display device may transmit light while displaying an image IM. Therefore, a user located in front of the transparent display device cannot only view the image IM displayed on the display device 10_5 but also view an object RS or the background located behind the transparent display device. When the display device 10_5 is applied to the transparent display device, a substrate of the display device 10_5 may include a light-transmitting portion that can transmit light or may be made of a material that can transmit light.

In concluding the detailed description, those skilled in the art will appreciate that many variations and modifications can be made to the embodiments without substantially departing from the aspects of the disclosure. Therefore, the disclosed embodiments of the disclosure are used in a generic and descriptive sense only and not for purposes of limitation.

What is claimed is:

1. A display device comprising:
a substrate;
a pixel electrode and a common electrode above the substrate, and spaced apart from each other;
a light-emitting element comprising a first contact electrode contacting the pixel electrode, and a second contact electrode contacting the common electrode;
a first repair material between the pixel electrode and the first contact electrode, and comprising an organic material comprising conductive particles; and
a second repair material between the common electrode and the second contact electrode, having a volume that is larger than a volume of the first repair material, and comprising an organic material comprising conductive particles.

2. The display device of claim 1, wherein the volume of the second repair material is about 1.1 times to about 3.0 times the volume of the first repair material.

3. The display device of claim 1, wherein the conductive particles comprise a conductive metal or carbon black.

4. The display device of claim 1, wherein the light-emitting element further comprises:
a semiconductor stack;
a conductive layer on one surface of the semiconductor stack; and
a protective film on three surfaces of the conductive layer, and on side surfaces of the semiconductor stack,
wherein the first contact electrode is on the protective film, and is connected to the conductive layer exposed through a hole defined by the protective film, and
wherein the second contact electrode is on the protective film in a hole penetrating a portion of the conductive layer and the semiconductor stack and having the second repair material filled therein.

5. The display device of claim 4, wherein the semiconductor stack further comprises:
a first semiconductor layer above the conductive layer and doped with a first conductive dopant;
an active layer on the first semiconductor layer; and
a second semiconductor layer on the active layer and doped with a second conductive dopant.

6. The display device of claim 5, wherein the semiconductor stack further comprises a third semiconductor layer on the second semiconductor layer and is undoped.

7. The display device of claim 6, wherein the semiconductor stack further comprises a light extraction pattern having a concave pattern on an upper portion.

8. The display device of claim 1, further comprising an organic layer between the pixel electrode and the common electrode.

9. The display device of claim 8, wherein the organic layer is not above the pixel electrode and the common electrode.

10. The display device of claim 5, wherein the hole penetrating the portion of the conductive layer and the semiconductor stack penetrates the conductive layer, the first semiconductor layer, and the active layer to expose the second semiconductor layer.

11. The display device of claim 10, wherein the second repair material is filled in the hole penetrating the portion of the conductive layer and the semiconductor stack to a height that is higher than the active layer.

12. A method for manufacturing a display device, the method comprising:
transferring light-emitting elements onto a pixel electrode and a common electrode;
inspecting a lighting status of the light-emitting elements;
removing a defective light-emitting element; and
bonding a repair light-emitting element to a position corresponding to the removed defective light-emitting element using a first repair material comprising an organic material comprising conductive particles applied onto the pixel electrode, and a second repair material comprising an organic material comprising conductive particles applied onto the common electrode, an amount of the first repair material being different from an amount of the second repair material.

13. The method of claim 12, wherein the bonding the repair light-emitting element to the position comprises applying the first repair material to a first height using a dispenser or an inkjet, and applying the second repair material to a second height that is higher than the first height.

14. The method of claim 13, wherein the repair light-emitting element comprises:
a semiconductor stack;
a conductive layer on one surface of the semiconductor stack;
a protective film on three surfaces of the conductive layer, and on side surfaces of the semiconductor stack;
a first contact electrode on the protective film, and connected to the conductive layer exposed through a hole defined by the protective film; and
a second contact electrode on the protective film, and in a hole penetrating the conductive layer and a portion of the semiconductor stack,
wherein the first contact electrode is aligned on the first repair material and the second contact electrode is aligned on the second repair material to bond the repair light-emitting element on the pixel electrode and the common electrode.

15. The method of claim 14, wherein the second repair material fills the hole penetrating the conductive layer and the portion of the semiconductor stack.

16. The method of claim 14, wherein the transferring the light-emitting elements onto the pixel electrode and the common electrode comprises:
locating an organic layer on the pixel electrode and the common electrode;
arranging one of the light-emitting elements on the organic layer;
locating a first connection electrode connecting the first contact electrode and the pixel electrode; and
locating a second connection electrode connecting the second contact electrode and the common electrode.

17. The method of claim 12, wherein the amount of the second repair material is about 1.1 times to about 3.0 times the amount of the first repair material.

18. The method of claim 12, wherein the conductive particles comprise a conductive metal or carbon black.

19. The method of claim 12, wherein the transferring the light-emitting elements onto the pixel electrode and the common electrode comprises contacting one of the light-emitting elements onto the pixel electrode and the common electrode using a bonding metal.

20. An electronic device comprising a display device for displaying an image, the display device comprising:
a substrate;
a pixel electrode and a common electrode above the substrate, and spaced apart from each other;
a light-emitting element comprising a first contact electrode contacting the pixel electrode, and a second contact electrode contacting the common electrode;
a first repair material between the pixel electrode and the first contact electrode, and comprising an organic material comprising conductive particles; and
a second repair material between the common electrode and the second contact electrode, having a volume that is larger than a volume of the first repair material, and comprising an organic material comprising conductive particles.
